(19) United States
(12) Patent Application Publication
(10) Pub. No.: US 2012/0119800 A1
(43) Pub. Date: May 17, 2012

(54) PLL FREQUENCY SYNTHESIZER

(75) Inventors: Hidetoshi Yamasaki, Hyogo (JP); Atsushi Ohara, Shiga (JP)

(73) Assignee: PANASONIC CORPORATION, Osaka (JP)

(21) Appl. No.: 13/357,419

(22) Filed: Jan. 24, 2012

Related U.S. Application Data
(63) Continuation of application No. PCT/JP2011/002134, filed on Apr. 11, 2011.

(30) Foreign Application Priority Data
Sep. 8, 2010 (JP) 2010-201307

(51) Int. Cl. H03L 7/08

(52) U.S. Cl. 327/142; 327/156

(57) ABSTRACT

In a digital PLL frequency synthesizer, after lock detection, first oscillating signal phase information is switched to second oscillating signal phase information by an estimation section based on previous oscillating signal phase information and a phase difference. As a result, the first oscillating signal phase information which has a risk of an error in the normal state (locked state) is not used. In addition, a conventional high-speed latch circuit for reclocking is not required. As a result, power consumption can be reduced, compared to the conventional art, while reducing or avoiding a degradation in phase-noise characteristics.

### CROSS-REFERENCE TO RELATED APPLICATIONS

This is a continuation of PCT International Application PCT/JP2011/002134 filed on Apr. 11, 2011, which claims priority to Japanese Patent Application No. 2010-201307 filed on Sep. 8, 2010. The disclosures of these applications including the specifications, the drawings, and the claims are hereby incorporated by reference in their entirety.

### BACKGROUND

The present disclosure generally relates to phase-locked loop (PLL) frequency synthesizers which are implemented as semiconductor integrated circuits and are used in wireless communication devices, wireless measuring devices, etc.

In recent years, the further miniaturization and speed increase of semiconductor devices have led to the use of a digital PLL frequency synthesizer which digitally controls a voltage controlled oscillator, instead of an analog PLL frequency synthesizer which controls an output frequency with an analog voltage using a charge pump circuit (see, for example, U.S. Pat. No. 6,326,851 (hereinafter referred to as PATENT DOCUMENT 1), Japanese Patent Publication No. 2002-76886 (hereinafter referred to as PATENT DOCUMENT 2), and R. B. STASZEWSKI and P. T. BALSARA, “ALL-DIGITAL FREQUENCY SYNTHESIZER IN DEEP-SUBMICRON CMOS,” Chap. 4, John Wiley and Sons, Inc., 2006 (hereinafter referred to as NON-PATENT DOCUMENT 1)).

Operation of a conventional digital PLL frequency synthesizer will be described with reference to the accompanying drawings. FIG. 17 is a block diagram showing a configuration of the conventional digital PLL frequency synthesizer 100. In FIG. 17, the digital PLL frequency synthesizer 100 includes a cumulative adder 111, a phase comparator 112, a digital loop filter 113, a gain adjuster 114, a digitally controlled oscillator 115, a sine-to-digital converter 121, a counter 116, latch circuits 117 and 120, a digital phase detector 118, and a reclock circuit 119.

The digital PLL frequency synthesizer 100 receives a reference signal FREF from an external reference quartz oscillator and a frequency control word FCW from an external register etc. The cumulative adder 111 accumulates the frequency control word FCW every cycle of the reference signal FREF to obtain reference phase information Rr[k], where [k] indicates a signal which is output in response to the k-th (k is an integer) transition of a clock for driving the cumulative adder 111.

Note that the frequency control word FCW is the ratio of the frequency of the reference signal FREF to the desired frequency of the output signal of the digitally controlled oscillator 115. Specifically, the desired frequency of the output signal of the digitally controlled oscillator 115 is represented by fosc=FCW×fr, where fosc is the desired frequency of the output signal of the digitally controlled oscillator 115, and fr is the frequency of the reference signal FREF. In general, FCW contains a decimal fraction, and fosc is set to a frequency higher than fr.

The output signal of the digitally controlled oscillator 115 is converted from a sine wave into a digital clock signal CKV by the sine-to-digital converter 121. The counter 116 counts the number of rising edges (the transition from ‘0’ to ‘1’ of a clock) of the clock signal CKV, and outputs a count value Rv[i] which changes in synchronization with the rising edge of the clock signal CKV, where [i] indicates a signal which is output in response to the i-th (i is an integer) transition of the clock signal CKV. The latch circuit 117 latches the count value Rv[i] every cycle of the reference signal FREF, and outputs the count value Rv[i] as oscillating signal phase information Rv[k].

A small phase difference ε (a resolution smaller than or equal to the cycle of the clock signal CKV) between the reference signal FREF and the clock signal CKV is detected by the digital phase detector 118 and is accumulated in the latch circuit 120 every cycle of the reference signal FREF, and the resulting value is output as ε[k].

These phase information items Rr[k], Rv[k], and ε[k] are subjected to addition and subtraction in the phase comparator 112 to obtain a phase error signal PHE[k] between the reference signal FREF and the clock signal CKV which is the output of the digitally controlled oscillator 115. High frequency components are removed from the phase error signal PHE[k] by the digital loop filter 113 and, for example, the gain of the oscillator 115 is adjusted by the gain adjuster 114, and thereafter, the resulting phase error signal PHE[k] is fed back to the oscillator 115. As a result, the frequency of the oscillator 115 is controlled.

FIG. 18 is a block diagram of the digital phase detector 118 which is described in PATENT DOCUMENT 2 or NON-PATENT DOCUMENT 1 (FIG. 4.13, etc.). FIG. 19 is a block diagram of a time-to-digital converter (TDC) 401 of FIG. 18. FIGS. 20A and 20B are timing charts for describing how the digital phase detector 118 of FIG. 18 calculates the phase difference ε.

In FIG. 19, the TDC 401 includes L (L is an integer of two or more) delay circuits 502 connected together in series, L latch circuits 504 which receive the respective outputs of the delay circuits 502, and an edge detector which receives L latch outputs Q(0)-Q(L−1).

As shown in FIG. 19, the clock signal CKV generated from the output signal of the oscillator 115 is input to the first-stage delay circuit 502, and the reference signal FREF is used as a clock for the latch circuits 504. As a result, the digital values Q(0)-Q(L−1) obtained by converting information about the phase difference between the clock signal CKV and the reference signal FREF are output from the respective latch circuits 504. The edge detector of FIG. 19 obtains, based on these values, phase information (ΔTr in FIG. 18) of the rising edge of the clock signal CKV and phase information (ΔTf in FIG. 18) of the falling edge of the clock signal CKV, and outputs the resulting values to a normalization circuit (NORM) 402 of FIG. 18. The normalization circuit (NORM) 402 calculates, based on the values of ΔTf and ΔTr, the phase difference “ε” between the rising edge of the reference signal FREF and the immediately following rising edge of the clock signal CKV, which is normalized by the time period of one cycle of the clock signal CKV. Specifically, for example, as shown in FIGS. 20A and 20B, ε=1−ΔTr/2(ΔTf−ΔTr) if ΔTr≦ΔTf, and ε=1−ΔTr/2(ΔTr−ΔTf) if ΔTr>ΔTf. Note the time resolution of ΔTf and ΔTr are the resolution of a delay time corresponding to one delay circuit stage of FIG. 19, and therefore, the phase difference ε has the same time resolution.

In general, the clock signal CKV generated from the output signal of the oscillator 115 is asynchronous with the reference signal FREF. Therefore, if the input data Rv[i] of the latch circuit 117 which changes in synchronization with the rising edge of the clock signal CKV is latched directly based on the reference signal FREF, there is a risk of a so-called metastable state. For example, as shown in FIG. 22A, if the rising edge of the reference signal FREF is close to the rising edge of the clock signal CKV, and therefore, ΔTr is close to a value which is smaller than or equal to the predetermined setup time or hold time of the latch circuit 117, the metastable state may occur, so that data which has changed based on the rising edge of the clock signal CKV cannot be correctly latched based on the reference signal FREF.

Therefore, in PATENT DOCUMENT 1 and NON-PATENT DOCUMENT 1, in order to reduce or avoid the risk, the reference signal FREF is latched based on the clock signal CKV as shown in FIG. 17. As a result, a clock signal CKR which is synchronous with the clock signal CKV and has substantially the same cycle as that of the reference signal FREF is generated by the reclock circuit 119. The latch circuit 117, the cumulative adder 111, and the latch circuit 120 are driven based on the reclocked clock signal CKR.

FIG. 21 shows an internal configuration of the reclock circuit 119, which is similar to that which is shown in FIG. 4.24 in NON-PATENT DOCUMENT 1. In FIG. 21, a reference character 1190 indicates a selector, reference characters 1191-1194 indicate latch circuits, and reference characters QP, QN, and QNP indicate the output signals of the latch circuits 1191, 1192, and 1193, respectively.

As described above, the clock signal CKR is generated by latching the reference signal FREF based on the clock signal CKV which is generated based on the output signal of the oscillator 115. If the reference signal FREF is latched based on only one of the rising edge and the falling edge of the clock signal CKV, there is a risk that the metastable state occurs even when the reference signal FREF is reclocked. For example, the reference signal FREF may be reclocked by being latched invariably only based on the rising edge of the clock signal CKV. In this case, as shown in FIG. 22A, if the rising edge of the reference signal FREF is close to the rising edge of the clock signal CKV, and ΔTr is close to a value which is smaller than or equal to the predetermined setup time or hold time of the latch circuit, the risk of the metastable state increases. On the other hand, the reference signal FREF may be reclocked by being latched invariably only based on the falling edge of the clock signal CKV. In this case, as shown in FIG. 22B, if the rising edge of the reference signal FREF is close to the falling edge of the clock signal CKV, and ΔTf is close to a value which is smaller than or equal to the predetermined setup time or hold time of the latch circuit, the risk of the metastable state increases.

These risks may be reduced or avoided to invariably perform stable reclocking as follows. As shown in FIG. 21, in the reclock circuit 119, the latch circuits 1191 and 1192 are provided which latch the reference signal FREF based on the rising edge and the falling edge, respectively, of the clock signal CKV. A signal on a channel which is latched based on one of the rising and falling edges of the clock signal CKV that is less likely to cause the metastable state, is selected using a select signal SEL_EDGE which is output from the digital phase detector 118 based on the phase difference ε between the reference signal FREF and the clock signal CKV. The selected signal CK is also latched based on the rising edge of the clock signal CKV to generate the clock signal CKR.

FIG. 23 is a timing chart showing changes in each signal until the phase error signal PHE[k] is output which is obtained when the reference signal FREF and the clock signal CKV have a predetermined phase relationship in a situation that the frequency of the PLL has converged to a desired value, where FCW=3.5.

In FIG. 23, firstly, a signal change in the vicinity of the n-th rising edge of the reference signal FREF will be described. A phase difference (time difference) between the n-th rising edge of the reference signal FREF and the immediately following rising edge of the clock signal CKV is almost one cycle of the clock signal CKV, and therefore, the phase difference (time difference) which is normalized by one cycle of the clock signal CKV is almost one (i.e., ε≈1). In this case, as shown in FIG. 23, the rising edge of the reference signal FREF is close to the rising edge of the clock signal CKV, and the rising edge of the reference signal FREF is farther from the falling edge of the clock signal CKV, and therefore, the selector 1190 in the reclock circuit of FIG. 21 selects the signal QNP, which is then latched by the latch circuit 1194, whereby the clock signal CKR is generated. At the rise of the clock signal CKR, the output Rv[i] of the counter 116 of FIG. 17, the calculated value of the cumulative adder 111, and the output ε of the digital phase detector 118 are latched, Rv[k], Rr[k], and ε[k] are output, and the phase comparator 112 outputs the phase error PHE[k](=Rr[k]−Rv[k]+ε[k]).

As described above, because FCW=3.5, when the frequency of the PLL has converged to the desired value, about 3.5 cycles of CKV clock are present in one cycle of the reference signal FREF as shown in FIG. 23. Therefore, the output ε of the digital phase detector 118 is almost 0.5 (ε≈0.5) in the vicinity of the next ((n+1)th) rising edge of the reference signal FREF. In this case, the rising edge of the reference signal FREF is close to the falling edge of the clock signal CKV, and the rising edge of the reference signal FREF is farther from the rising edge of the clock signal CKV. Therefore, the selector 1190 of the reclock circuit of FIG. 21 selects the signal QP, which is then latched by the latch circuit 1194, whereby the clock signal CKR is generated. At the rise of the clock signal CKR, the output Rv[i] of the counter 116 of FIG. 17, the calculated value of the cumulative adder 111, and the output ε of the digital phase detector 118 are latched, Rv[k], Rr[k], and ε[k] are output, and the phase comparator 112 outputs the phase error PHE[k] (=Rr[k]−Rv[k]+ε[k]).

As described above, in the conventional digital PLL frequency synthesizer 100, the reference signal FREF is latched based on both the rising and falling edges of the clock signal CKV generated from the output signal of the oscillator 115, and one of the latched signals that is less likely to cause the metastable state is selected based on the phase difference between the reference signal FREF and the clock signal CKV to generate the clock signal CKR. The latch circuit in each block as well as the latch circuit 117 are driven based on the clock signal CKR. As a result, the risk of the metastable state in the latch circuit 117 due to the asynchronicity of the clock signal CKV and the reference signal FREF is avoided. However, as shown in FIG. 21, in order to perform stable reclocking, the reclock circuit 119 is required which includes the latch circuits 1191-1194 which are driven based on the clock signal CKV having a higher rate than that of the reference signal FREF. Therefore, in the conventional digital PLL frequency synthesizer 100, to reduce or avoid the metastable state of the latch circuit 117 disadvantageously leads to an increase in power consumption.

### SUMMARY

The present disclosure describes implementations of a digital PLL frequency synthesizer which has less power consumption compared to the conventional art and in which the metastable state caused by the asynchronicity of the output signal of the oscillator and the reference signal can be reduced or avoided.

An example PLL frequency synthesizer according to the present disclosure includes a digitally controlled oscillator configured to output an oscillating signal having an oscillation frequency corresponding to a digital control code, a counter configured to count the number of waves of an oscillating signal, and output the count value, a first latch circuit configured to latch the count value every cycle of a reference signal, and output the resulting value as first oscillating signal phase information, an oscillating signal phase information estimation section configured to estimate an output value of the first latch circuit, and output the resulting value as second oscillating signal phase information, a digital phase detector configured to output, as a digital value, a phase difference value between the reference signal and the oscillating signal, a second latch circuit configured to latch the phase difference value every cycle of the reference signal, and output the resulting value as phase difference information, a selector configured to switch an output signal from the first oscillating signal phase information to the second oscillating signal phase information, based on a lock detection signal, a third latch circuit configured to latch the output of the selector every cycle of the reference signal, and output the resulting value as third oscillating signal phase information, a cumulative adder configured to cumulatively add a frequency control word for setting the oscillation frequency of the oscillator, every cycle of the reference signal, and output the resulting value as reference phase information, a phase comparator configured to calculate a phase error from the reference phase information, the phase difference information, and the third oscillating signal phase information, and output a phase error signal, and an oscillation frequency controller configured to receive the output signal of the phase comparator, and output the digital control code.

Thus, the PLL frequency synthesizer does not use the output of the first latch circuit which has a risk of the metastable state in the normal state (locked state). Therefore, the metastable state caused by the asynchronicity of the output signal and the reference signal can be reduced or avoided without using a reclock circuit, which is employed in the conventional art. In addition, a high-speed latch circuit for reclocking is not required, and therefore, power consumption can be reduced compared to the conventional art.

In the example PLL frequency synthesizer of the present disclosure, the output of the counter is not used in the normal state (locked state), and therefore, the counter operation may be stopped in a mode in which the selector selects the second oscillating signal phase information.

Thus, in the PLL frequency synthesizer, the counter operation which is driven based on a high-speed oscillating signal clock is stopped in the normal state (locked state), whereby power consumption can be further reduced.

Another example PLL frequency synthesizer of the present disclosure includes a digitally controlled oscillator configured to output an oscillating signal having an oscillation frequency corresponding to a digital control code, a counter configured to count the number of waves of an oscillating signal, and output the count value, a first latch circuit configured to latch the count value every cycle of a reference signal using a first clock signal, and output the resulting value as first oscillating signal phase information, a digital phase detector configured to output, as a digital value, a phase difference value between the reference signal and the oscillating signal, a second latch circuit configured to latch the phase difference value every cycle of the reference signal, and output the resulting value as phase difference information, a third latch circuit configured to latch the count value based on a second clock signal, latch the latched value every cycle of the reference signal using the first clock signal, and output the resulting value as second oscillating signal phase information, a selector configured to select one of the first oscillating signal phase information, the second oscillating signal phase information, and a value obtained by adding a predetermined value to the second oscillating signal phase information, and output the selected value as third oscillating signal phase information, a cumulative adder configured to cumulatively add a frequency control word for setting the oscillation frequency of the oscillator, every cycle of the reference signal, and output the resulting value as reference phase information, a phase comparator configured to calculate a phase error from the reference phase information, the phase difference information, and the third oscillating signal phase information, and output a phase error signal, and an oscillation frequency controller configured to receive the output signal of the phase comparator, and output the digital control code.

Thus, the PLL frequency synthesizer uses two latch circuits for latching a count value using different clocks, to select and use one of latch outputs that has a lower risk of the metastable state, depending on the phase difference information. Therefore, the metastable state caused by the asynchronicity of the output signal and the reference signal can be reduced or avoided without using a reclock circuit, which is employed in the conventional art. In addition, a high-speed latch circuit for reclocking is not required, and therefore, power consumption can be reduced compared to the conventional art.

According to the present disclosure, a digital PLL frequency synthesizer can be provided in which power consumption can be reduced compared to the conventional art, and the metastable state caused by the asynchronicity of the clock signal generated from the output signal of the oscillator and the reference signal can be reduced or avoided.

### BRIEF DESCRIPTION OF THE DRAWINGS

FIG. 1 is a block diagram schematically showing a configuration of a digital PLL frequency synthesizer according to a first embodiment of the present disclosure.

FIG. 2 is a block diagram schematically showing a configuration of an oscillating signal phase information estimation section in the first embodiment of the present disclosure.

FIG. 3 is a timing chart for describing the principle of estimation of oscillating signal phase information in the first embodiment of the present disclosure.

FIG. 4 is a block diagram schematically showing a configuration of a latch determination circuit in the first embodiment of the present disclosure.

FIG. 5 is a flow chart for describing operation of the latch determination circuit of FIG. 4.

FIG. 6 is a block diagram showing a configuration of a comparative example digital PLL frequency synthesizer.

FIG. 7 is a diagram showing the result of a simulation of operation of the digital PLL frequency synthesizer of the first embodiment of the present disclosure etc.

FIG. 8 is a block diagram showing a variation of the digital PLL frequency synthesizer of the first embodiment of the present disclosure.

FIG. 9 is a block diagram schematically showing a configuration of a digital PLL frequency synthesizer according to a second embodiment of the present disclosure.

FIG. 10 is a block diagram schematically showing a configuration of an oscillating signal phase information estimation section in the second embodiment of the present disclosure.

FIG. 11 is a timing chart for describing a selection method of the oscillating signal phase information selector in the second embodiment of the present disclosure.

FIG. 12 is a block diagram showing a variation of the digital PLL frequency synthesizer of the second embodiment of the present disclosure.

FIG. 13 is a block diagram schematically showing a configuration of an oscillating signal phase information selector in FIG. 12.

FIG. 14 is a timing chart for describing a selection method of the oscillating signal phase information selector in the variation of the second embodiment of the present disclosure.

FIG. 15 is a block diagram schematically showing a configuration of a wireless communication device as an example application of the present disclosure.

FIG. 16 is a perspective view of a television set including the wireless communication device of FIG. 15.

FIG. 17 is a block diagram schematically showing a configuration of a conventional digital PLL frequency synthesizer.

FIG. 18 is a block diagram schematically showing a configuration of a digital phase detector.

FIG. 19 is a block diagram schematically showing a configuration of a time-to-digital converter (TDC) used in the digital phase detector.

FIGS. 20A and 20B are timing charts for describing how the digital phase detector calculates a phase difference E.

FIG. 21 is a block diagram schematically showing a configuration of a reclock circuit used in a conventional digital PLL frequency synthesizer.

FIGS. 22A and 22B are timing charts showing an example phase relationship between a reference signal and a clock signal generated from the output of an oscillator.

FIG. 23 is a timing chart for describing operation of a reclock circuit.

### DETAILED DESCRIPTION

Embodiments of the present disclosure will be described in detail hereinafter with reference to the accompanying drawings. Note that the same components as those of the conventional art are indicated by the same reference characters, and the descriptions thereof which are similar to those described in the background section will be omitted as much as possible.

### First Embodiment

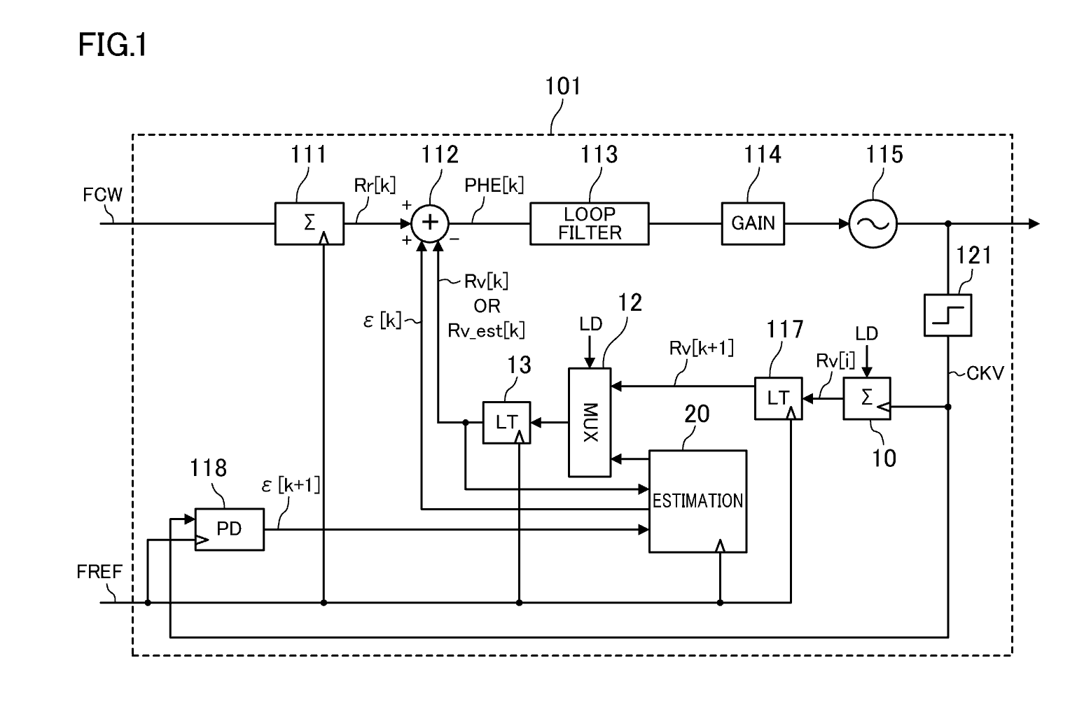

FIG. 1 is a block diagram schematically showing a configuration of a digital PLL frequency synthesizer according to a first embodiment of the present disclosure. In FIG. 1, similar to the conventional digital PLL frequency synthesizer 100, the digital PLL frequency synthesizer 101 includes a cumulative adder 111, a phase comparator 112, a digital loop filter 113, a gain adjuster 114, a digitally controlled oscillator 115, a sine-to-digital converter 121, a latch circuit 117, and a digital phase detector 118, but does not include a reclock circuit, which is conventionally used. The digital PLL frequency synthesizer 101 further includes a counter 10 with an enable terminal, a selector 12, a latch circuit 13, and an oscillating signal phase information estimation section 20.

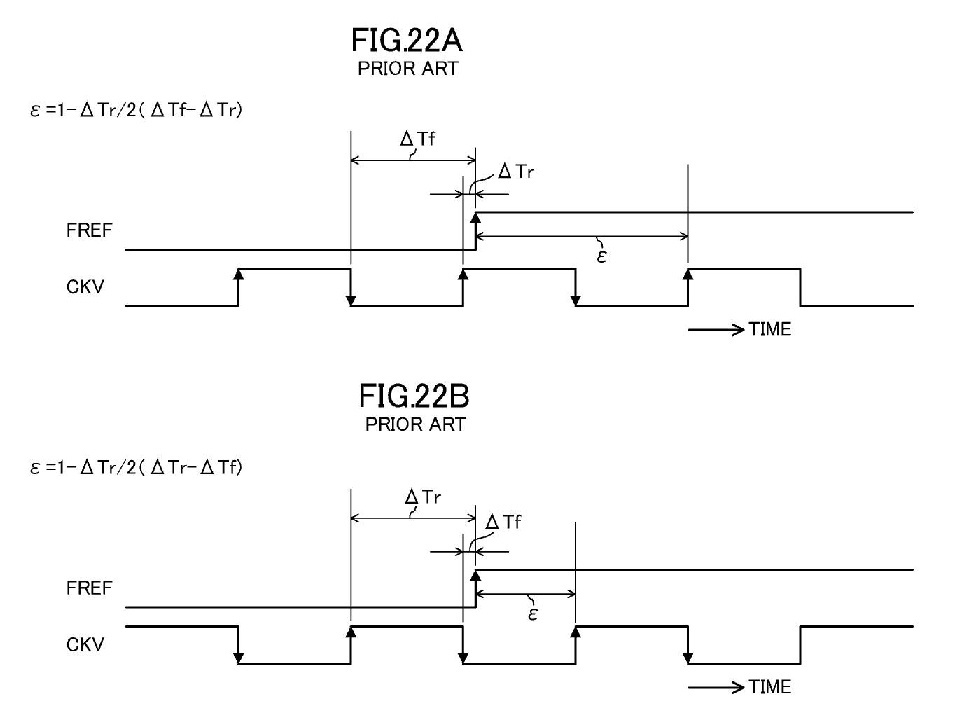

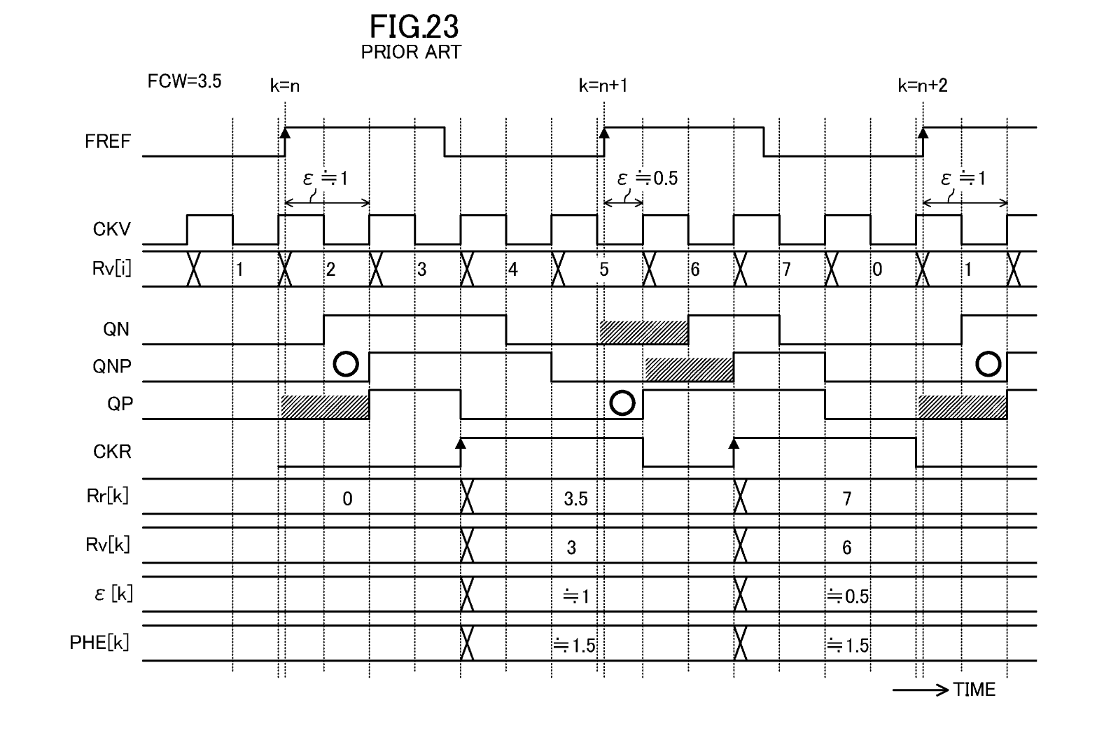

As shown in FIG. 1, unlike the conventional art, the digital PLL frequency synthesizer 101 uses the reference signal FREF directly (i.e., without reclocking) as a clock for driving the cumulative adder 111, the latch circuits 117 and 13, and the oscillating signal phase information estimation section 20. Therefore, in the latch circuit 117, there remains the risk that the metastable state occurs due to the asynchronicity of the clock signal CKV generated from the output signal of the oscillator 115 and the reference signal FREF. Therefore, if the metastable state occurs, the latch circuit 117 may output an incorrect value as first oscillating signal phase information. Note that, as shown in FIG. 22A, the metastable state occurs when the rising edge of the clock signal CKV is close to the rising edge of the reference signal FREF, and the time difference ΔTr therebetween is smaller than or equal to the predetermined setup time or hold time of the latch circuit 117. In general, ΔTr of FIG. 22A is less often smaller than or equal to the predetermined setup time or hold time of the latch circuit 117, than is not the case, i.e., than is greater than the predetermined setup time or hold time of the latch circuit 117. Therefore, the frequency at which the latch circuit 117 outputs an incorrect value is typically lower than the frequency at which the latch circuit 117 outputs a correct value.

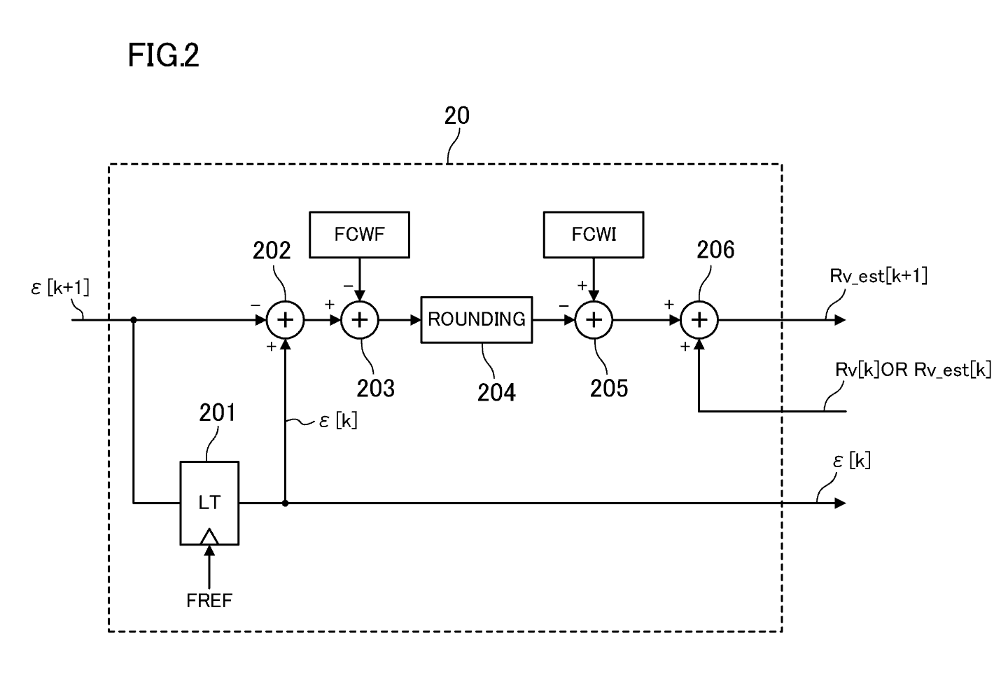

FIG. 2 is a block diagram showing an example configuration of the oscillating signal phase information estimation section 20. In FIG. 2, the oscillating signal phase information estimation section 20 includes a latch circuit 201, subtractors 202, 203, and 205, a rounding circuit 204, and an adder 206. In the oscillating signal phase information estimation section 20 of FIG. 2, the subtractor 202 calculates a difference (ε[k]−ε[k+1]) between a phase difference (time difference) ε[k+1] between the (k+1)th transition (rising edge) of the reference signal FREF and the immediately following rising edge of the clock signal CKV, which is normalized by the time period of one cycle of the clock signal CKV, and the k-th phase difference ε[k] of the reference signal FREF one cycle before. The subtractor 203 subtracts the fractional part FCWF of FCW from the calculated value. The rounding circuit 204 rounds the resulting value of the subtractor 203, and outputs the resulting value 0 or 1 to the subtractor 205. The subtractor 205 subtracts the input value from the integer part FCWI of FCW. Thereafter, the adder 206 adds the resulting value of the subtractor 205 to the output of the latch circuit 13. The resulting value Rv_est[k+1] of the adder 206 is estimated to be a value which would be correctly latched based on the (k+1)th rising edge of the reference signal FREF by the latch circuit 117. The value Rv_est[k+1] is output as second oscillating signal phase information.

An external lock detector (not shown) determines whether or not the PLL is in a predetermined stable state (e.g., the frequency of the PLL has converged to the desired value), and outputs the result as a lock detection signal LD. Based on the lock detection signal LD, the selector 12 selects the output of the latch circuit 117, i.e., the first oscillating signal phase information Rv, until a predetermined period of time has elapsed since the transition of the PLL to the stable state, and selects the output of the oscillating signal phase information estimation section 20, i.e., the second oscillating signal phase information Rv_est, when the predetermined period of time has elapsed since the transition of the PLL to the stable state, and outputs the selected information to the latch circuit 13. The latch circuit 13 latches and outputs the selected signal to the phase comparator 112 and the oscillating signal phase information estimation section 20. Therefore, at the time that the select signal Rv[k+1] (or Rv_est[k+1]) is input to the latch circuit 13 at the (k+1)th transition of the reference signal FREF, the output of the latch circuit 13 is the output Rv[k] (or Rv_est[k]) of the latch circuit 117 (or the oscillating signal phase information estimation section 20) which is obtained one cycle of the reference signal FREF before that time.

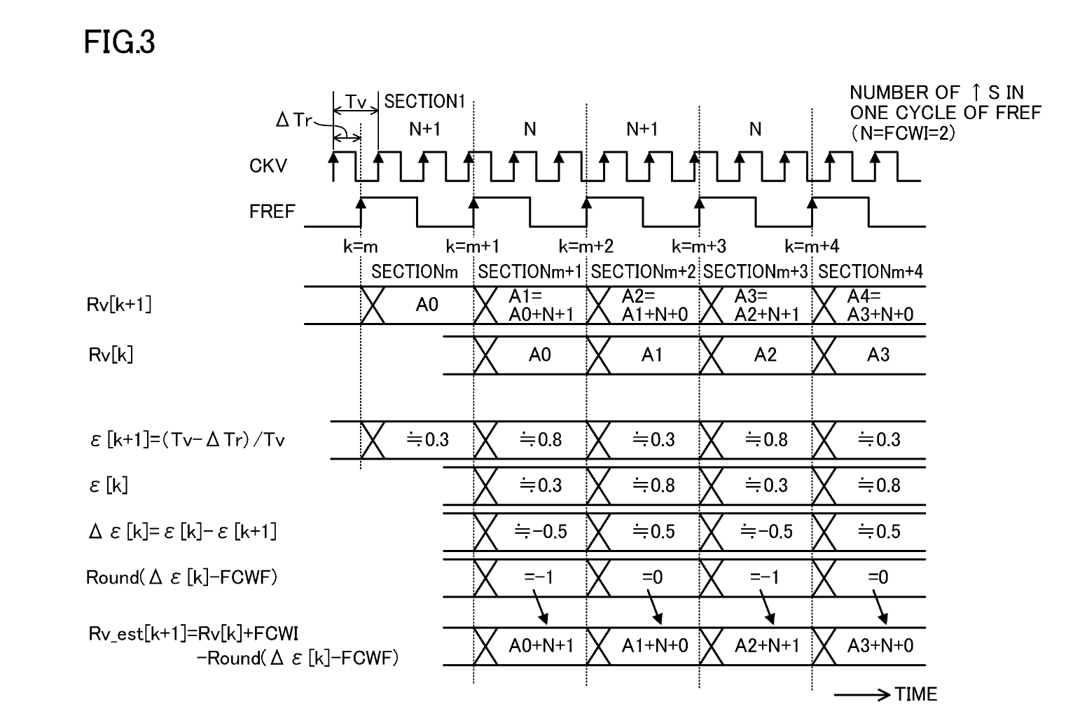

FIG. 3 is a timing chart for describing that the counter value Rv[k+1] can be estimated which would be obtained when the latch circuit 117 is correctly latched based on the (k+1)th rising edge of the reference signal FREF as described above. Specifically, FIG. 3 shows changes in the phase difference ε and the oscillating signal phase information Rv and Rv_est, etc. which occur when the reference signal FREF and the clock signal CKV have a predetermined phase relationship in a situation that the frequency of the PLL has converged to the desired value, where FCW=2.5.

The counter 10 of FIG. 1 is driven based on the rising edge of the clock signal CKV to increase the count value. Therefore, an increase in the count value per cycle of the reference signal FREF corresponds to the number of rising edges of the clock signal CKV present in a one-cycle section of the reference signal FREF. When the frequency of the PLL has converged to the desired value, the number of rising edges of the clock signal CKV in each one-cycle section of the reference signal FREF is N or N+1, where N is the integer part (FCWI) of FCW, as shown in FIG. 3. In FIG. 3, N=2 because FCW=2.5 as described above.

In FIG. 3, a section between the m-th rising edge and the (m+1)th rising edge of the reference signal FREF is represented by a section m (m is an integer). The outputs Rv[k+1] of the latch circuit 117 in the sections m-(m+4) are represented by A0, A1, A2, A3, and A4, respectively. The increase (N+1) of the count value in the section m is latched by the latch circuit 117 based on the (m+1)th rising edge of the reference signal FREF. Therefore, the output A1 of the latch circuit 117 immediately after the (m+1)th rise of the reference signal FREF is (A0+N+1). Similarly, as shown in FIG. 3, the output An of the latch circuit 117 immediately after the (m+n)th (n is an integer of two or more) rise of the reference signal FREF is An−1+(the increase of the count value in the section (m+n−1)). Because the latch circuit 117 and the latch circuit 13 are driven in synchronization with each other using the same reference signal FREF, the output Rv[k] of the latch circuit 13 which is obtained when the selector 12 of FIG. 1 selects the output of the latch circuit 117 is the output of the latch circuit 117 which is delayed by one cycle of the reference signal FREF as shown in FIG. 3.

Next, a relationship between a fluctuation in the phase difference ε between the rising edge of the reference signal FREF when the PLL has converged, and the immediately following rising edge of the clock signal CKV, and FCW, will be described. Note that, as shown in FIG. 3, a phase difference ε between the rising edge of the reference signal FREF and the immediately following rising edge of the clock signal CKV is represented by (Tv−ΔTr)/Tv, where ΔTr is a time difference between the rising edge of the reference signal FREF and the immediately following rising edge of the clock signal CKV, and Tv is the time period of one cycle of the clock signal CKV. The integer part of FCW is represented by FCWI, and the fractional part of FCW is represented by FCWF. In the example of FIG. 3, because it is assumed that FCW=2.5, FCWI=2 and FCWF=0.5.

When the frequency of the PLL has converged to the desired value, about FCW clock signals CKV are present per cycle of the reference signal FREF. Therefore, if FCW=2.5, about 2.5 clock signals CKV are present. Therefore, as shown in FIG. 3, when the phase difference ε[m+1] corresponding to the m-th rising edge of the reference signal FREF is about 0.3, the phase difference ε[m+2] corresponding to the next (m+1)th rising edge of the reference signal FREF is about 0.8, which is different from the previous phase difference by about FCWF (=0.5).

The relationship between a change in the phase difference ε and FCWF, which is specifically illustrated in FIG. 3, is represented by the following general expression:

ε[k+1]≈ mod(ε[k]−FCWF,1) (1)

where mod(A, 1) is the modulo operation, which finds the remainder of division of A by 1. For example, mod(A, 1)=0.3 if A=0.3, and mod(A, 1)=1−0.2=0.8 if A=−0.2. Therefore, ε[k+1] is represented by:

ε[k+1]≈ε[k]−FCWF for ε[k]−FCWF≦0 (2)

ε[k+1]≈1+(ε[k]−FCWF) for ε[k]−FCWF<0 (3)

Based on expression (1), the value Δε[k] which is obtained by subtracting the input ε[k+1] of the latch circuit 201 of FIG. 2 from the output ε[k] is represented by:

$$Δɛ [ k ] = ɛ [ k ] - ɛ [ k + 1 ] \approx ɛ [ k ] - mod ( ɛ [ k ] - FCWF , 1 ) \qquad ( 4 )$$

Next, a relationship between the increase in the count value of the counter 10 (i.e., the number of rising edges of the clock signal CKV present in one section of the reference signal FREF) and the fluctuation in ε will be described.

As can be seen from the relationship in FIG. 3 between the fluctuation (from about 0.3 to about 0.8) in the value of the phase difference ε at the m-th and (m+1)th rising edges of the reference signal FREF, and the increase in the count value of the counter 10 in the section m, Δε has a negative value if the increase in the count value of the counter 10 in a section k of the reference signal FREF is (FCWI+1). In other words, in expression (4) of Δε, the value of the modulo operation is greater than ε[k]. Therefore, if the increase in the count value of the counter 10 is (FCWI+1), ε[k]−FCWF<0. Therefore, based on expression (3), expression (4) is represented by:

Δε[k]≈ε[k]−{1+(ε[k]−FCWF)} (5)

On the other hand, as can be seen from the relationship in FIG. 3 between the fluctuation (from about 0.8 to about 0.3) in the value of the phase difference ε at the (m+1)th and (m+2)th rising edges of the reference signal FREF, and the increase in the count value of the counter 10 in the section (m+1), Δε has a value of 0 or more if the increase in the count value of the counter 10 in a section k of the reference signal FREF is FCWI. In other words, in expression (4) of Δε, the value of the modulo operation is smaller than or equal to ε[k]. Therefore, if the increase in the count value of the counter 10 is FCWI, expression (4) is represented by the following expression based on expression (2):

Δε[k]≈ε[k]−(ε[k]−FCWF) (6)

Therefore, the correct count value Rv[k+1] of the latch circuit 117 latched based on the (k+1)th rising edge of the reference signal FREF is represented by the following expression using a carry C (C=0 or 1):

Rv[k+1]=Rv[k]+FCWI+C (7)

If C=1, the following expression is obtained from expression (5):

Δε[k]−FCWF≈−1 (8)

If C=0, the following expression is obtained from expression (6):

Δε[k]−FCWF≈0 (9)

Based on expression (8), if C=1, the value of Round(Δε[k]−FCWF) which rounds (Δε[k]−FCWF) is −1. Based on expression (9), if C=0, the value of Round(Δε[k]−FCWF) which rounds (Δε[k]−FCWF) is 0. Therefore, the value of the carry C is invariably represented by:

C=−Round(Δε[k]−FCWF) (10)

Therefore, based on expressions (7) and (10), the following relationship is established:

Rv[k+1]=Rv[k]+FCWI−Round(Δε[k]−FCWF) (11)

The digital PLL frequency synthesizer of the first embodiment of the present disclosure has an additional function of finding that, if the previous output value Rv[k] of the latch circuit 117 is correct, the relationship of expression (11) between the correct value of the current output value Rv[k+1], the previous output value Rv[k], the fluctuation Aε[k] in the phase difference between the previous and current output values, and FCW is established, and estimating a count value which is obtained when the latch circuit 117 correctly latches, based on expression (11) using the latch circuit 117, the selector 12, the latch circuit 13, and the oscillating signal phase information estimation section 20 of FIGS. 1 and 2.

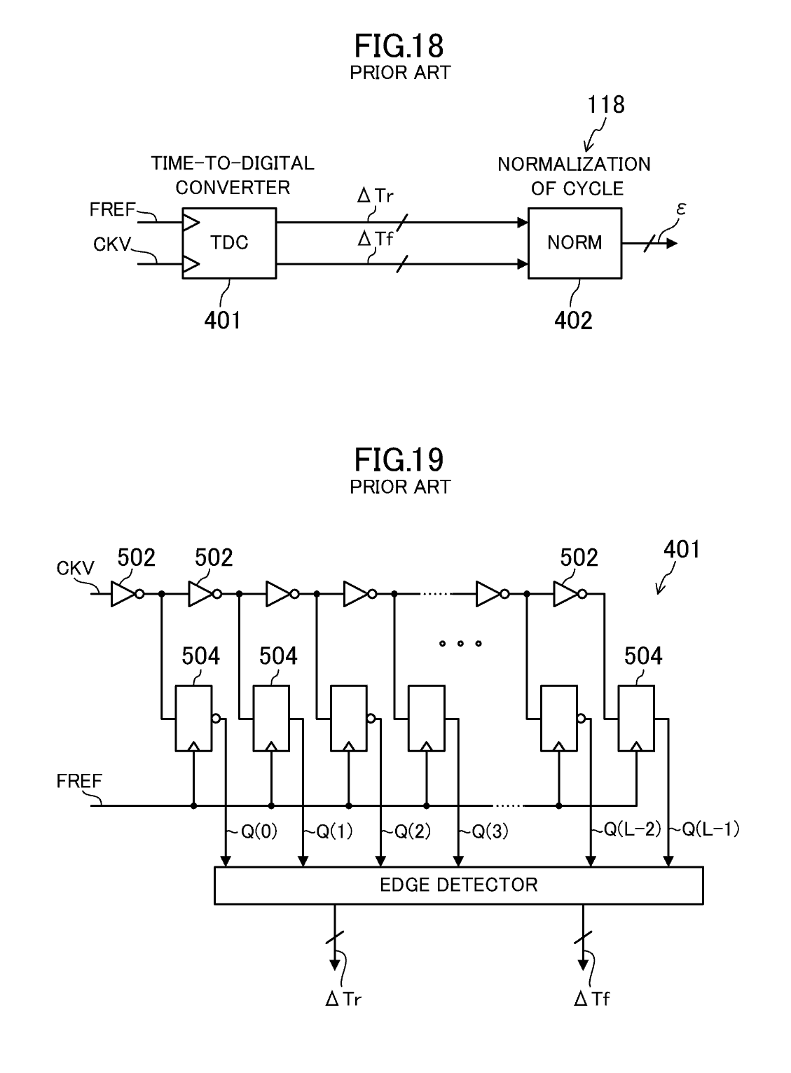

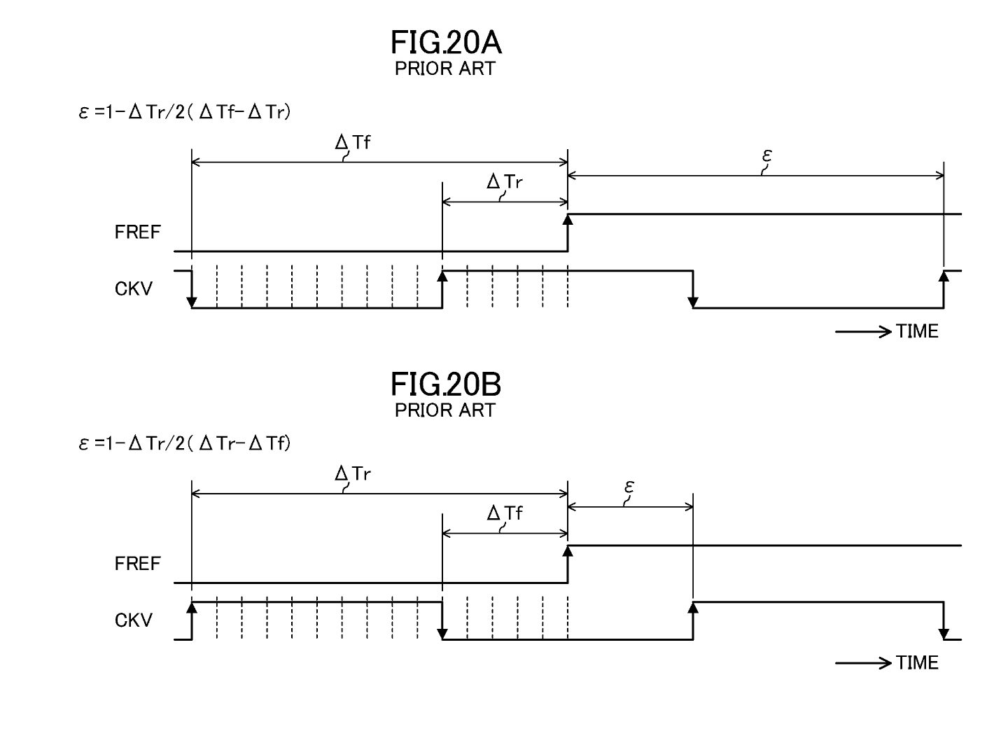

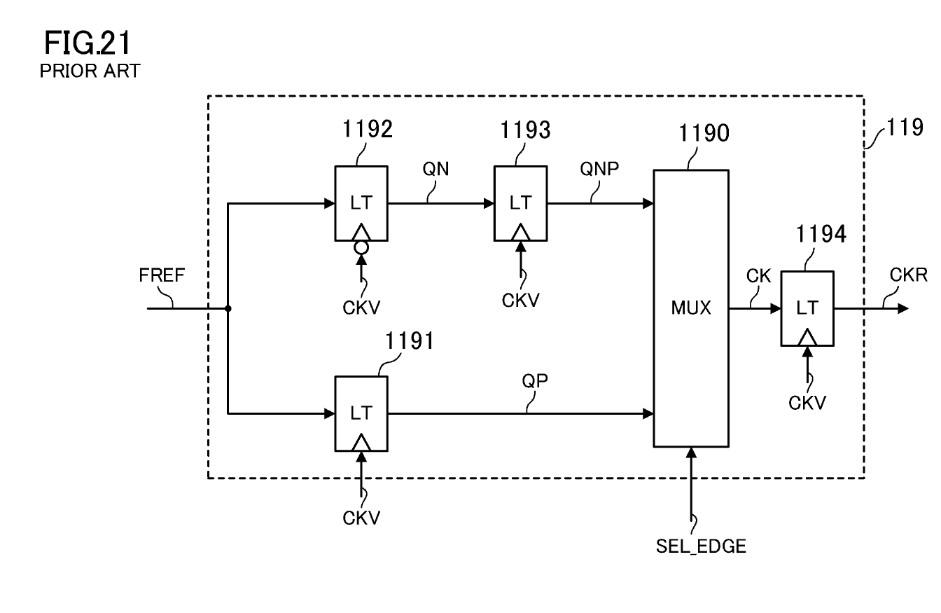

Note that, in this embodiment, the relationship of expression (8) or (9) is established between Δε and FCWF, depending on the value of the carry C of expression (7), and therefore, the carry C is determined based on Δε and FCWF using a round function as in expression (10). Specifically, the carry C of expression (7) is determined so that C=1 if Δε[k]−FCWF≦−0.5, and C=0 if Δε[k]−FCWF>−0.5. The method of determining the carry C is not limited to this. A basic fluctuation (hereinafter referred to as a reference value of Δε) in Δε is FCWF. It may be assumed that an error from the reference value of Δε which is estimated from the time resolution of the TDC 401 of FIG. 18, the phase-noise characteristics of the digitally controlled oscillator 115 itself, etc., is E (E>0), i.e., FCWF−E<Δε<FCWF+E. In this case, for example, the carry C may be determined by comparing Δε[k]−FCWF with a predetermined value using a comparator circuit as follows: C=0 if Δε[k]−FCWF≧−E, and C=1 otherwise.

As described above, in the latch circuit 117, there remains the risk that the metastable state occurs due to the asynchronicity of the clock signal CKV generated from the output signal of the oscillator 115 and the reference signal FREF, and therefore, the previous output value Rv[k] of the latch circuit 117 does not invariably have a correct value. Therefore, if the previous output value Rv[k] is incorrect, a value estimated based on that value is also, of course, incorrect, and therefore, the oscillating signal phase information estimation section 20 outputs an incorrect estimated value. Also, however, as described above, the metastable state occurs when, as shown in FIG. 22A, the rising edge of the clock signal CKV is close to the rising edge of the reference signal FREF, and the time difference ΔTr therebetween is smaller than or equal to the predetermined setup time or hold time of the latch circuit 117. Although it depends on the performance of the latch circuit, ΔTr of FIG. 22A is typically less often smaller than or equal to the setup time or hold time of the latch circuit, than is not the case, i.e., than is greater than the setup time or hold time of the latch circuit. Therefore, the frequency at which the latch circuit 117 outputs an incorrect value is typically lower than the frequency at which the latch circuit 117 outputs a correct value. At least, the latch circuit 117 does not invariably output an incorrect value, and sometimes outputs a correct value.

A correct current output value of the latch circuit 117 is estimated from the correct output value Rv[k] of the latch circuit 117 based on expression (11) to generate a correct estimation result Rv_est[k+1], which is then used instead of the output value Rv[k+1] of the latch circuit 117 at the next ((k+2)th) transition of the reference signal FREF. Once such operation is performed, correct oscillating signal phase information can be output to the phase comparator 112 at the k-th and following transitions of the reference signal FREF.

Therefore, the digital PLL frequency synthesizer of the first embodiment of the present disclosure determines whether or not the previous output value Rv[k] is correct, using the lock detection signal LD.

If the output Rv[k] of the latch circuit 117 has an incorrect value, and the value is selected by the selector 12, incorrect oscillating signal phase information is output to the phase comparator 112. Therefore, although it depends on the desired frequency accuracy, if a predetermined high level of frequency accuracy is desired, the frequency accuracy of the PLL may not converge to a desired value. Therefore, a condition for lock detection may be, for example, that the oscillation frequency has converged to the desired frequency accuracy for a predetermined period of time or more. When the condition is satisfied, the lock detection signal LD may be output from a lock detector (the value of LD may be changed from 1 to 0), and the selector 12 may switch the signal output to the latch circuit 13 from the output signal of the latch circuit 117 to the output signal of the oscillating signal phase information estimation section 20, immediately after the lock detection signal LD is input (the value of LD is changed to 0) (or alternatively, after the value of LD continues to be 0 for a predetermined period of time).

Thus, the digital PLL frequency synthesizer of the present disclosure does not use the output of the latch circuit 117 which has the risk of the metastable state in the normal state (locked state). Therefore, the metastable state caused by the asynchronicity of the output signal CKV and the reference signal FREF can be reduced or avoided without using a reclock circuit, which is employed in the conventional art. Also, a high-speed latch circuit for reclocking is not required, and therefore, power consumption can be reduced compared to the conventional art.

After the selector 12 switches the output signal from the output signal of the latch circuit 117 to the output signal of the oscillating signal phase information estimation section 20, the counter 10 which has been used until that time is no longer required. The lock detection signal LD or a signal related thereto may be used as an enable signal for the counter 10, and the counter operation may be stopped, depending on the switching timing of the output signal of the selector 12.

Thus, by stopping the counter 10 which operates based on the high-rate clock signal CKV, power consumption can be further reduced compared to conventional digital PLL frequency synthesizers.

In the above description, the lock detection condition is that the oscillation frequency has converged to the desired frequency accuracy for a predetermined period of time or more, and the selector 12 performs signal switching based on the condition. The lock detection condition used for the signal switching performed by the selector 12 is not limited to this. For example, the lock detection condition may be that the fluctuation in the output Rv of the latch circuit 117 has converged within a predetermined range for a predetermined period of time or more. For example, as described with reference to FIG. 3 etc., when the oscillation frequency of the PLL has converged to the desired frequency accuracy, the fluctuation in Rv (the increase in the output value of the latch circuit 117) takes a value which is equal to either FCWI or (FCWI+1). In other words, the carry C is 0 or 1. Therefore, if the fluctuation in Rv takes a value other than these values, at least one of the previous and current values of the output Rv is incorrect. Conversely, if the fluctuation in Rv is equal to either FCWI or (FCWI+1), it is highly likely that the previous value of the output Rv is correct. Therefore, for example, the lock detection signal LD may be output from a lock detector (not shown) (e.g., the value of LD is changed from 1 to 0) if the output Rv of the latch circuit 117 continues to be equal to either FCWI or (FCWI+1) for a predetermined period of time (e.g., 128 cycles of the reference signal FREF).

Alternatively, the following lock detection condition may be provided. For example, the lock detection signal LD may be output from a lock detector (not shown) (e.g., the value of LD is changed from 1 to 0) if the output Rv[k+1] of the latch circuit 117 is equal to the output Rv_est[k+1] of the oscillating signal phase information estimation section 20 (or the equality continues to be maintained for a predetermined period of time).

If the desired frequency accuracy of the PLL frequency synthesizer is not high, the desired frequency accuracy may be satisfied even when the output Rv of the latch circuit 117 is incorrect. Therefore, if the desired frequency accuracy of the PLL frequency synthesizer is not high, it is preferable to use the value of the output Rv of the latch circuit 117 for the lock detection condition as in the above example.

Note that, as in the above example, if the value of the output Rv of the latch circuit 117 is used for the lock detection condition, then when the counter 10 is invariably stopped, depending on the switching timing of the output signal of the selector 12, the lock detection signal LD continues to be output even if the oscillation frequency of the PLL deviates from the desired value due to some sudden external noise etc.

Therefore, if the value of the output Rv of the latch circuit 117 is used for the lock detection condition, the counter 10 may be intermittently operated to check the converged state of the PLL after the counter 10 is stopped, depending on the switching timing of the output signal of the selector 12.

Alternatively, the above lock detection condition employing the value of the output Rv of the latch circuit 117 may be used as a first lock detection condition, and a second lock detection condition may be further provided that the oscillation frequency has converged to the desired frequency accuracy for a predetermined period of time or more. The lock detection signal LD may be output to the selector 12 or the counter 10 (e.g., the value of LD is changed from 1 to 0) only if the two lock detection conditions are simultaneously satisfied, and the counter 10 may be invariably stopped when the lock detection signal LD in in the locked state (the value of LD is 0).

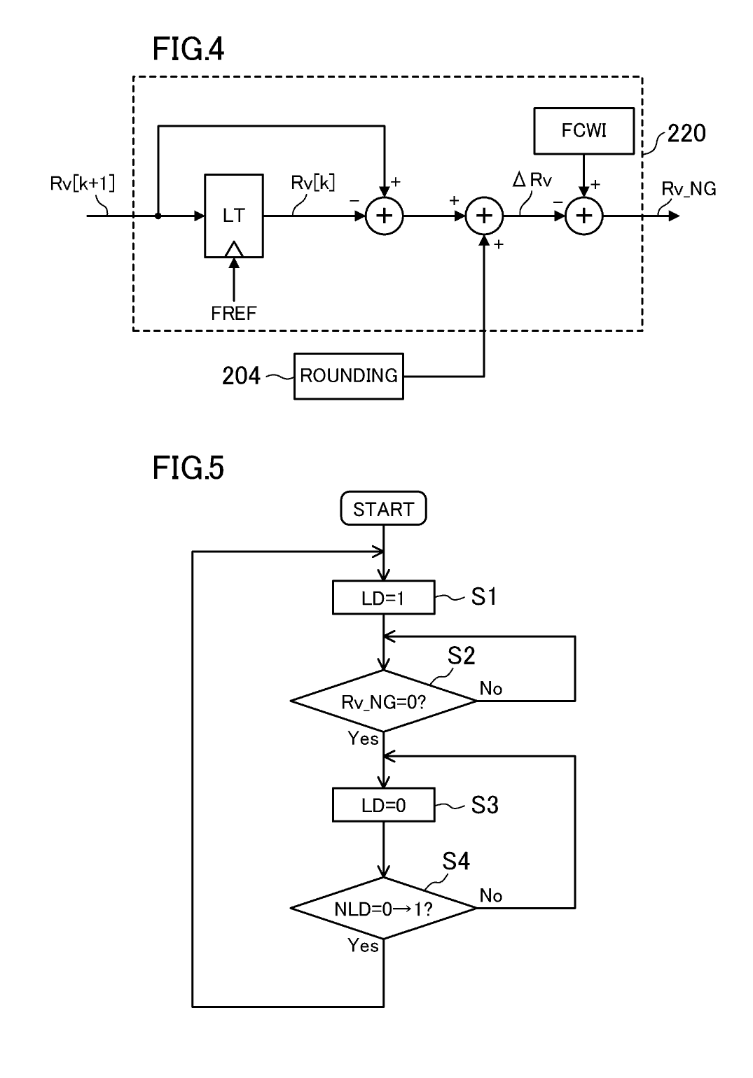

For example, as shown in FIG. 4, a latch determination circuit 220 may be provided which latches the output Rv[k+1] of the latch circuit 117 using the reference signal FREF as in the latch circuit 117 to generate Rv[k], adds the output of the rounding circuit 204 in the phase information estimation section 20 to a difference between Rv[k+1] and Rv[k] to generate the signal ΔRv, and outputs a signal Rv_NG indicating a difference between ΔRv and FCWI. The lock detection signal LD which is used for the signal switching performed by the selector 12 may be switched based on the flow of FIG. 5.

When the outputs Rv[k] and Rv[k+1] of the latch circuit 117 at the k-th and (k+1)th rising edges of the reference signal FREF have correct values, the following relationship is established based on expression (11):

Rv[k+1]−Rv[k]+Round(Δε[k]−FCWF)=FCWI (12)

Therefore, if the output Rv_NG of the latch determination circuit 220 is 0, the value of Rv[k] used in the estimation performed by the oscillating signal phase information estimation section 20 is correct, and the estimated value Rv_est[k+1] also has a correct value.

Therefore, that Rv_NG is 0 is used as the first lock detection condition. As shown in the flow of FIG. 5, as an initial state, the first the lock detection signal LD is set to 1 (S1). It is determined whether or not Rv_NG is 0 (S2). If Rv_NG is 0, LD is changed from 1 to 0, and the output of the selector 12 is switched from the output of the latch circuit 117 to the output of the oscillating signal phase information estimation section 20 (S3). In addition, the operation of the counter 10 is stopped. A lock condition which is typically commonly used (e.g., the oscillation frequency has converged to the desired frequency accuracy for a predetermined period of time or more) is used as the second lock detection condition, to determine whether or not a second lock detection signal NLD corresponding to the second lock detection condition has been switched from the locked state to the unlocked state (S4). If the second lock detection condition is not satisfied, the first lock detection signal LD is set to 1 (S1), and the operation of the counter 10 is resumed, and the determination of whether or not Rv_NG is 0 is repeatedly performed until Rv_NG is 0 (S2).

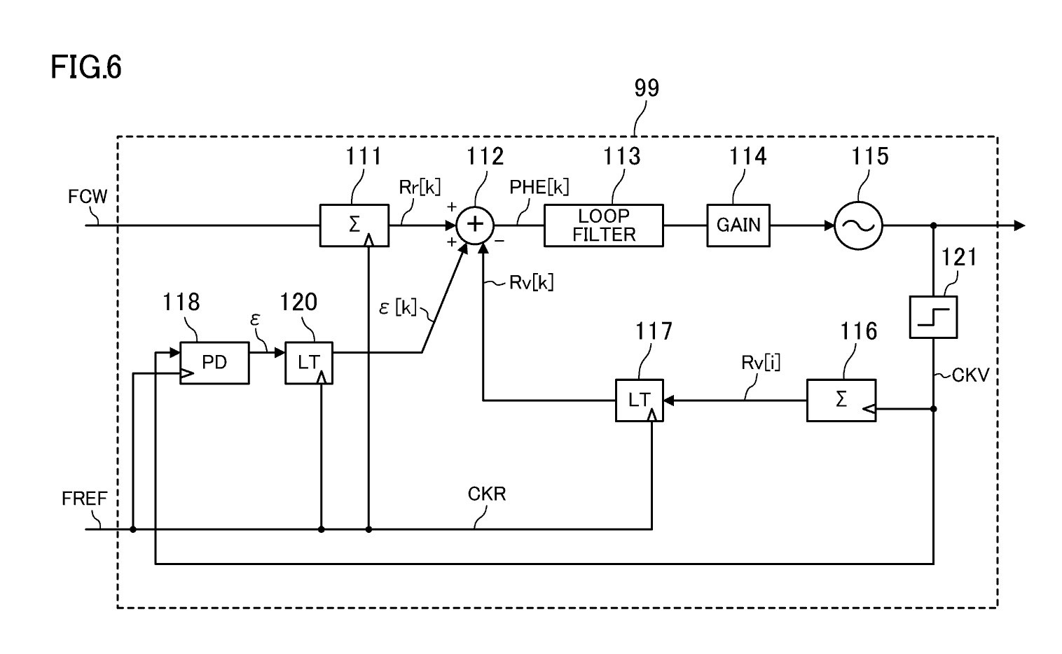

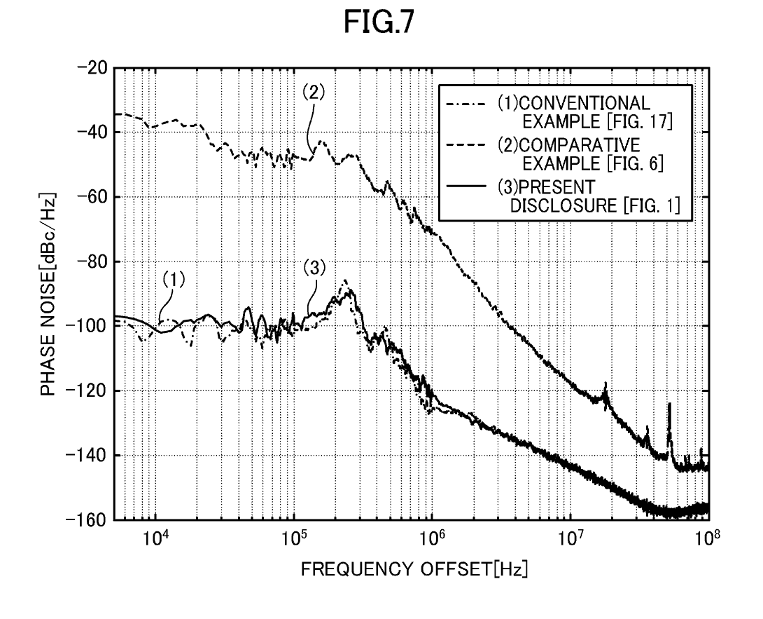

Thus, various lock detection conditions can be used. As an example, FIG. 7 ((3) in FIG. 7) shows the result (phase-noise characteristics) of a simulation of the operation of the digital PLL frequency synthesizer 101, where the lock detection signal LD is output if the fluctuation in the output Rv of the latch circuit 117 has continued to be either FCWI or FCWI+1 for a predetermined period of time (128 cycles of the reference signal FREF). Note that, for comparison, FIG. 7 also shows the result ((1) in FIG. 7) of a simulation of the operation of the conventional digital PLL frequency synthesizer 100, and the result ((2) in FIG. 7) of a simulation of a digital PLL frequency synthesizer 99 of FIG. 6 in which none of the conventional reclock circuit 119 and the oscillating signal phase information estimation section 20 of this embodiment is provided, and the latch circuit 117 is simply driven based on the reference signal FREF. In the simulation results (2) and (3) of FIG. 7, the error of the value of the output Rv caused by the metastable state in the latch circuit 117 is pseudo-added by outputting a value which is smaller by one than the correct output value of Rv with a probability of ½ when the phase difference ε is 0.01 or less or 0.99 or more. When the latch circuit 117 is simply driven based on the reference signal FREF ((2) in FIG. 7), the phase-noise characteristics are significantly degraded due to the error caused by the metastable state. In the digital PLL frequency synthesizer 101 of this embodiment, even if the error caused by the metastable state sometimes occurs in the latch circuit 117, phase-noise characteristics similar to those of the conventional digital PLL frequency synthesizer 100 employing the reclock circuit 119 are obtained without a problem.

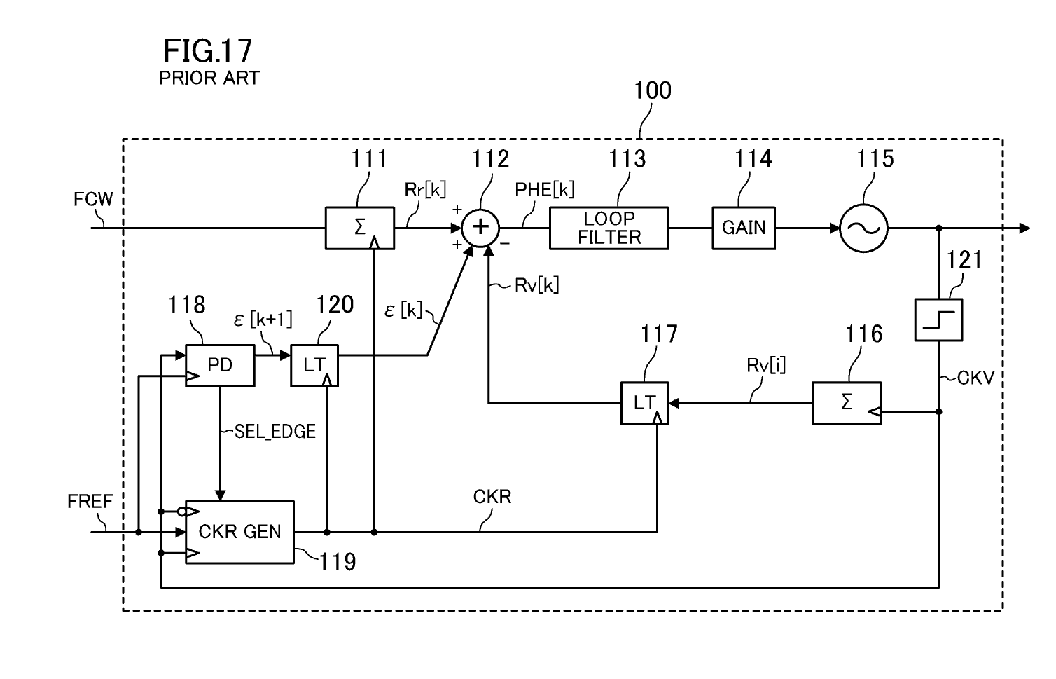

Note that, in the digital PLL frequency synthesizer 101 of the first embodiment, the latch circuit 201 (corresponding to the conventional latch circuit 120 of FIG. 17) in the oscillating signal phase information estimation section 20 is the only circuit that latches the phase difference ε which is the output signal of the digital phase detector 118. The number of latch circuit stages is not limited to this. Any number of stages of circuits may be provided as long as the timing relationship between the phase difference ε input to the phase comparator 112 and the oscillating signal phase information Rv (or Rv_est) is established as in FIG. 3.

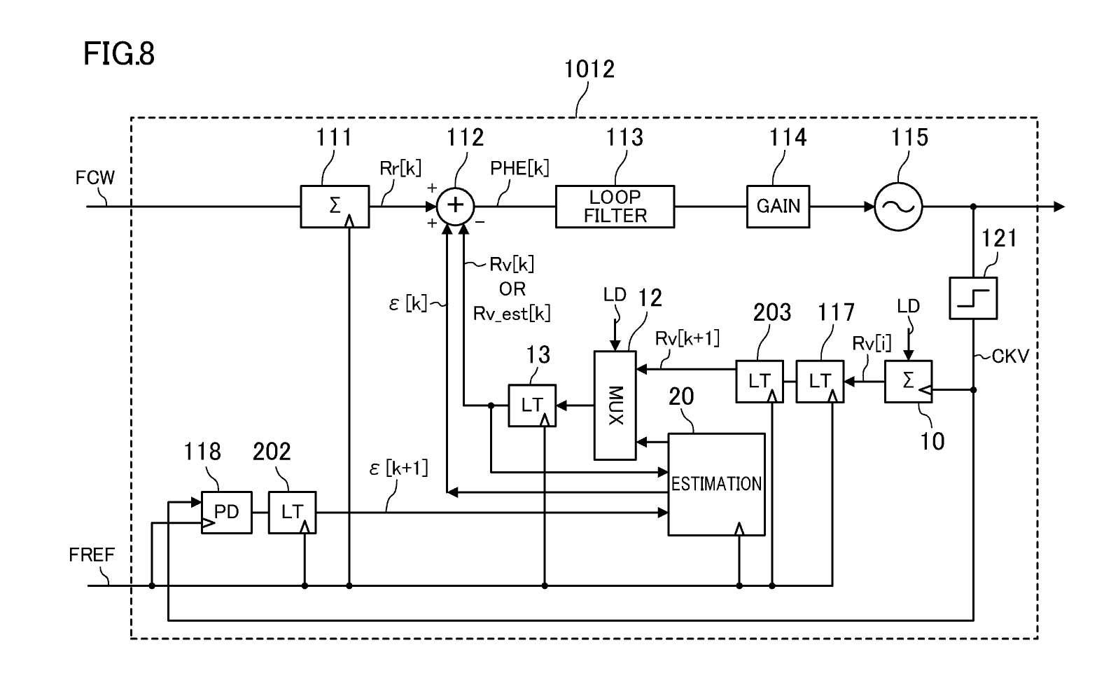

For example, as in latch circuits 202 and 203 in a digital PLL frequency synthesizer 1012 shown in FIG. 8, the same number of (a plurality of) latch circuits may be provided on a path between the digital phase detector 118 and the oscillating signal phase information estimation section 20 of FIG. 1 and on a path between the latch circuit 117 and the selector 12.

### Second Embodiment

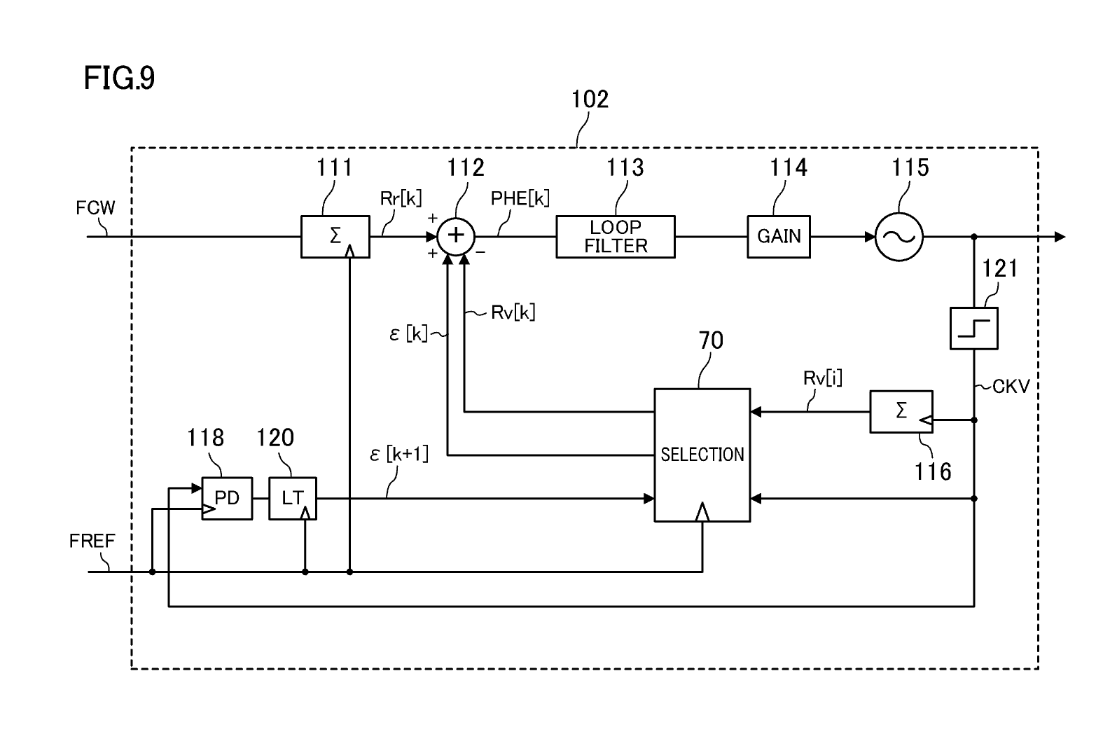

FIG. 9 is a block diagram schematically showing a configuration of a digital PLL frequency synthesizer 102 according to a second embodiment of the present disclosure. In FIG. 9, the digital PLL frequency synthesizer 102 does not include a reclock circuit, which is conventionally employed, as with the digital PLL frequency synthesizer 101 of the first embodiment. The digital PLL frequency synthesizer 102 includes a counter 116 which is employed in the conventional art, instead of the counter 10 with an enable terminal of the digital PLL frequency synthesizer 101 of the first embodiment. The digital PLL frequency synthesizer 102 also includes an oscillating signal phase information selector 70 instead of the selector 12, the latch circuit 13, and the oscillating signal phase information estimation section 20 of the digital PLL frequency synthesizer 101 of the first embodiment.

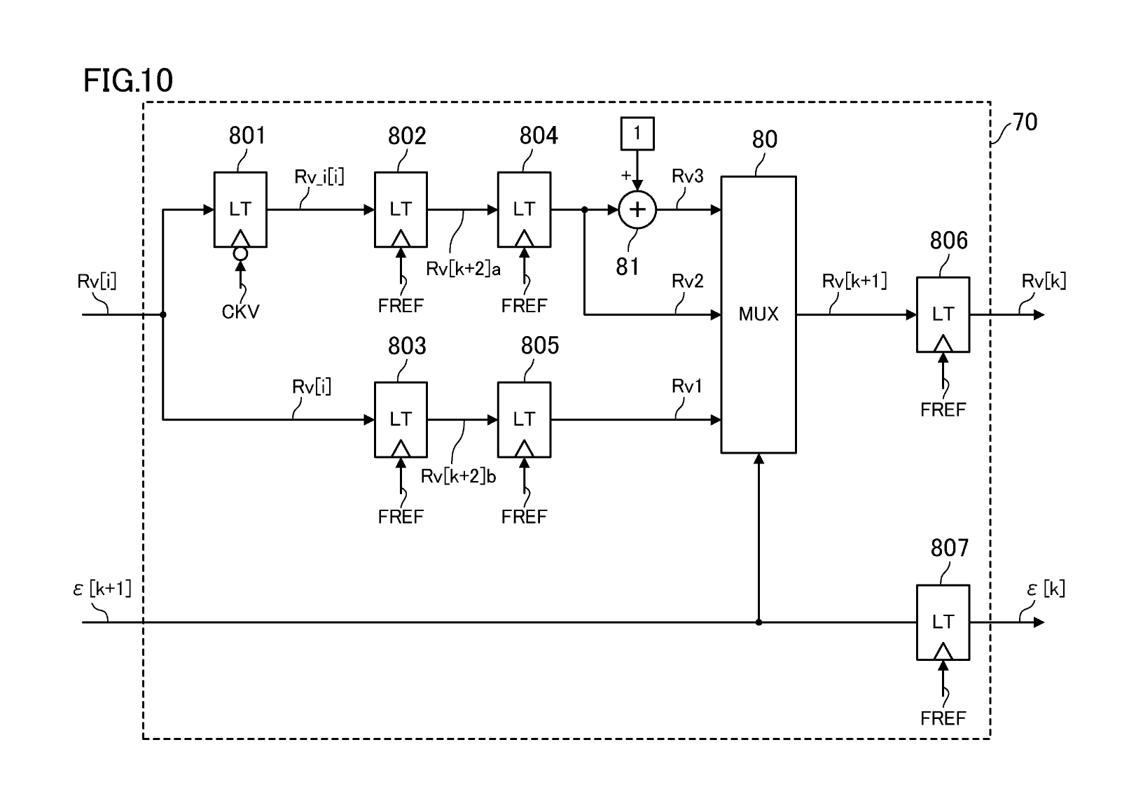

FIG. 10 is a block diagram showing an example configuration of the oscillating signal phase information selector 70. As shown in FIG. 10, the oscillating signal phase information selector 70 includes a latch circuit 801 which latches oscillating signal phase information Rv[i] output from the counter 116 based on the falling edge of the clock signal CKV generated from the output signal of the oscillator 115, a plurality of latch circuits 802-807 which latch input signals using the reference signal FREF, an adder 81, and a selector 80.

In the oscillating signal phase information selector 70, the output Rv_i[i] of the latch circuit 801 is latched twice by the latch circuits 802 and 804 using the reference signal FREF, and thereafter, the output Rv2 of the latch circuit 804 is input to the adder 81 and the selector 80. The adder 81 adds one to Rv2 and outputs the resulting value Rv3 to the selector 80. On the other hand, the oscillating signal phase information Rv[i] is latched twice by the latch circuits 803 and 805 using the reference signal FREF, and thereafter, the output Rv1 of the latch circuit 805 is input to the selector 80. Here, the output of the latch circuit 802 is represented by Rv[k+2]a, and the output of the latch circuit 803 is represented by Rv[k+2]b.

As described in the background section, the clock signal CKV is asynchronous with the reference signal FREF, and therefore, there is a risk that the metastable state occurs in the latch circuits 802 and 803. If the metastable state occurs, an incorrect value may be output. Note that a change in data input to the latch circuit 802 is delayed by half the cycle of the clock signal CKV from a change in data input to the latch circuit 803, and therefore, typically, the metastable state does not occur simultaneously in the latch circuits 802 and 803. Therefore, the selector 80 selects input data having a low risk of the metastable state from Rv1, Rv2, and Rv3, depending on the value of the phase difference ε[k+1] between the clock signal CKV and the reference signal FREF, and outputs oscillating signal phase information Rv[k+1] to the latch circuit 806. The latch circuit 806 latches the oscillating signal phase information Rv[k+1] using the reference signal FREF, and outputs oscillating signal phase information Rv[k].

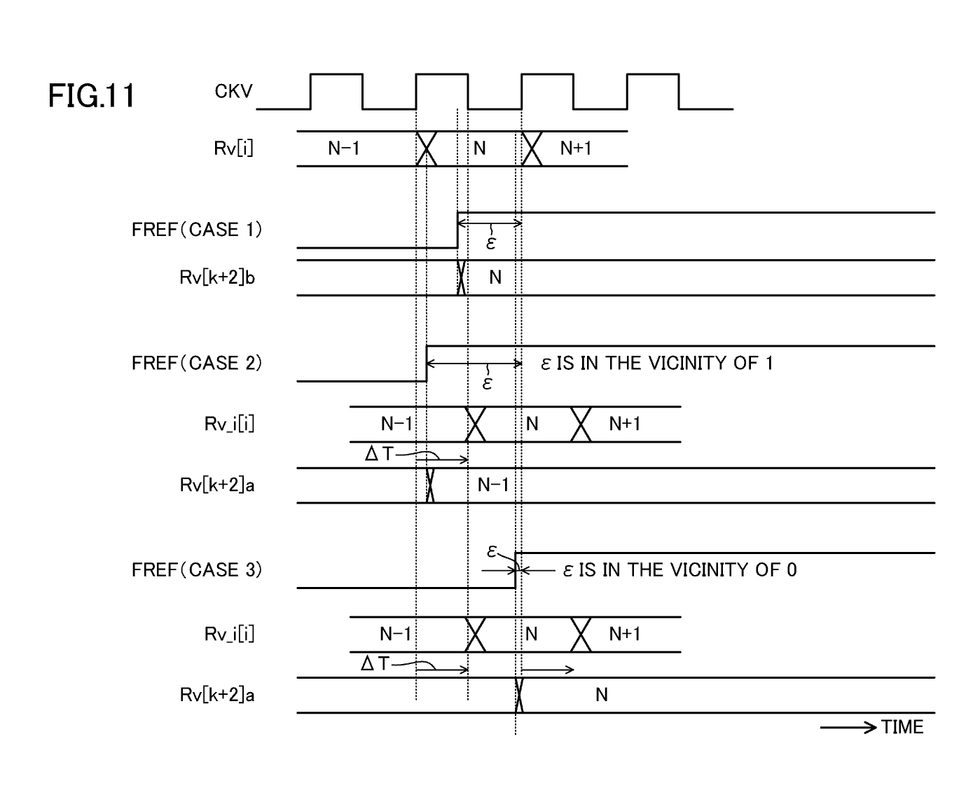

FIG. 11 is a diagram for describing that the correct oscillating signal phase information Rv[k+1] can be invariably generated by selecting one of Rv1, Rv2, and Rv3, depending on the phase difference ε in the oscillating signal phase information selector 70 as described above.

As shown for the reference signal FREF (case 1) of FIG. 11, when a space between the rising edges of the clock signal CKV and the reference signal FREF is large enough to satisfy the specified setup time or hold time of the latch circuit, there is not a risk that the metastable state occurs in the latch circuit 803, and the correct oscillating signal phase information Rv[k+1] can be output by the selector 80 selecting Rv1 from the inputs Rv1, Rv2, and Rv3.

Also, as shown for the reference signal FREF (case 2) and the reference signal FREF (case 3) of FIG. 11, when the space between the rising edges of the clock signal CKV and the reference signal FREF is close enough to fail to satisfy the specified setup time or hold time of the latch circuit, there is not a risk that the metastable state occurs in the latch circuit 802 which latches input data which is obtained by delaying data Rv[i] which is changed at the rising edge of the clock signal CKV by a predetermined period of time ΔT (here, half the cycle of the clock signal CKV). Note that, as shown for the reference signal FREF (case 2) of FIG. 11, when the phase difference ε is greater than a normalized value which is obtained by dividing ΔT by the time period of one cycle of the clock signal CKV, a value obtained by subtracting one from Rv[i] may be latched instead of the Rv[i] which should be originally latched, due to the delay of the value data. Therefore, in the case of the reference signal FREF (case 2) of FIG. 11, if the selector 80 selects a value (i.e., Rv3) obtained by adding one to Rv2 from the inputs Rv1, Rv2, and Rv3, the selector 80 can output the correct oscillating signal phase information Rv[k+1]. As shown for the reference signal FREF (case 3) of FIG. 11, when the phase difference ε is smaller than the normalized value which is obtained by dividing ΔT by the time period of one cycle of the clock signal CKV, the value Rv[i] which should be originally latched is latched even if the delayed data is latched. In the case of the reference signal FREF (case 3) of FIG. 11, if the selector 80 selects Rv2 from the inputs Rv1, Rv2, and Rv3, the selector 80 can output the correct oscillating signal phase information Rv[k+1].

For example, when ΔT is half the cycle of the clock signal CKV as in this embodiment, Rv2 is selected if 0≦ε<0.25, Rv1 is selected if 0.25≦ε<0.75, and Rv3 is selected if 0.75≦ε<1. In this case, the specified setup time or hold time of the latch circuit can be maximized.

Note that the selection of the oscillating signal phase information (Rv1, Rv2, Rv3) by the selector 80, depending on the value ε, is not limited to the above values, and can be flexibly determined as long as the specified setup time or hold time of the latch circuit is satisfied.

In this embodiment, the delay time ΔT of the oscillating signal phase information Rv[i] is half the cycle of the clock signal CKV, and the oscillating signal phase information Rv[i] is delayed by half the cycle by being latched based on the falling edge of the clock signal CKV. The delay time ΔT is not limited to this. For example, if the specified value of the setup time or hold time of the latch circuit is 1/10 of the time period Tv of one cycle of the clock signal CKV, the latch circuit 801 may latch using a clock which is obtained by delaying the clock signal CKV using a delay circuit so that ΔT is greater than 2/10 of Tv, e.g., ΔT is about 3/10 of Tv. In this case, the selector 80 may select oscillating signal phase information (Rv1, Rv2, Rv3), depending on the value of ε, as follows. Rv2 may be selected if 0≦ε<a threshold 1, Rv1 may be selected if the threshold 1≦ε<a threshold 2, and Rv3 may be selected if the threshold 2≦ε<1. In this case, the threshold 1 may be greater than 0.1 and smaller than 0.2 (e.g., 0.15), and the threshold 2 may be greater than 0.8 and smaller than 0.9 (e.g., 0.85).

Thus, in this embodiment of the present disclosure, the oscillating signal phase information selector 70 including a plurality of latch circuits which are driven using the low-rate reference signal FREF is used instead of the conventional reclock circuit 119 which requires a large number of latch circuits which are driven using the clock signal CKV which has a higher rate than that of the reference signal FREF. Therefore, a risk that an error occurs in the oscillating signal phase information Rv[k] due to the metastable state can be reduced or avoided. In addition, the number of high-speed latch circuits for reclocking can be reduced compared to the conventional art, whereby power consumption can be reduced compared to the conventional art.

<<Variations>>

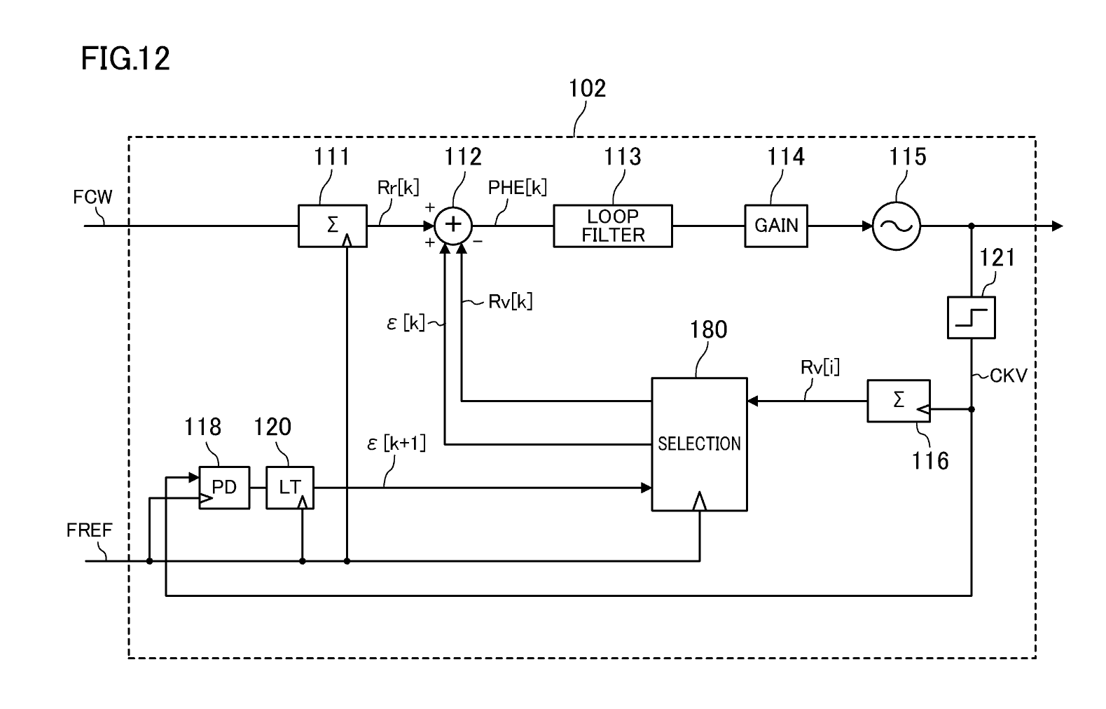

FIG. 12 is a block diagram showing a variation of the digital PLL frequency synthesizer 102 of the second embodiment of the present disclosure. In the oscillating signal phase information selector 70 of FIG. 10, a latch output which has a lower risk of the metastable state is selected based on phase difference information using the latch circuit 801 which delays the oscillating signal phase information Rv[i] to generate the data Rv_i[i] and the latch circuit 803 which latches the oscillating signal phase information Rv[i] as in the conventional art. Alternatively, in an oscillating signal phase information selector 180 of FIG. 13, a latch circuit 801 which is driven using a clock signal FREF_d which is obtained by delaying the reference signal FREF by a predetermined period of time ΔT using a buffer 84 etc., instead of delaying the oscillating signal phase information Rv[i], may be provided. A latch output which has a lower risk of the metastable state is selected based on phase difference information ε[k+1] using oscillating signal phase information Rv2 and Rv3 generated from data output from the latch circuit 801, and oscillating signal phase information Rv1 generated from data output from the latch circuit 803 which latches the oscillating signal phase information Rv[i] using the reference signal FREF as in the conventional art.

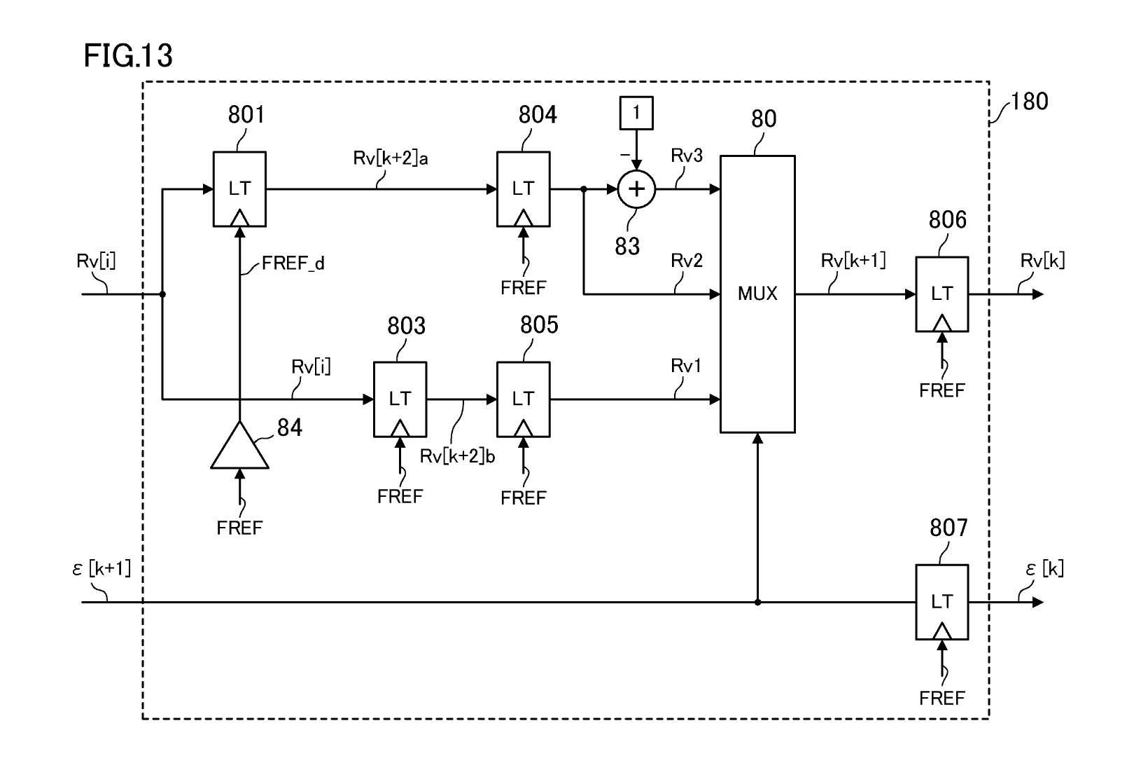

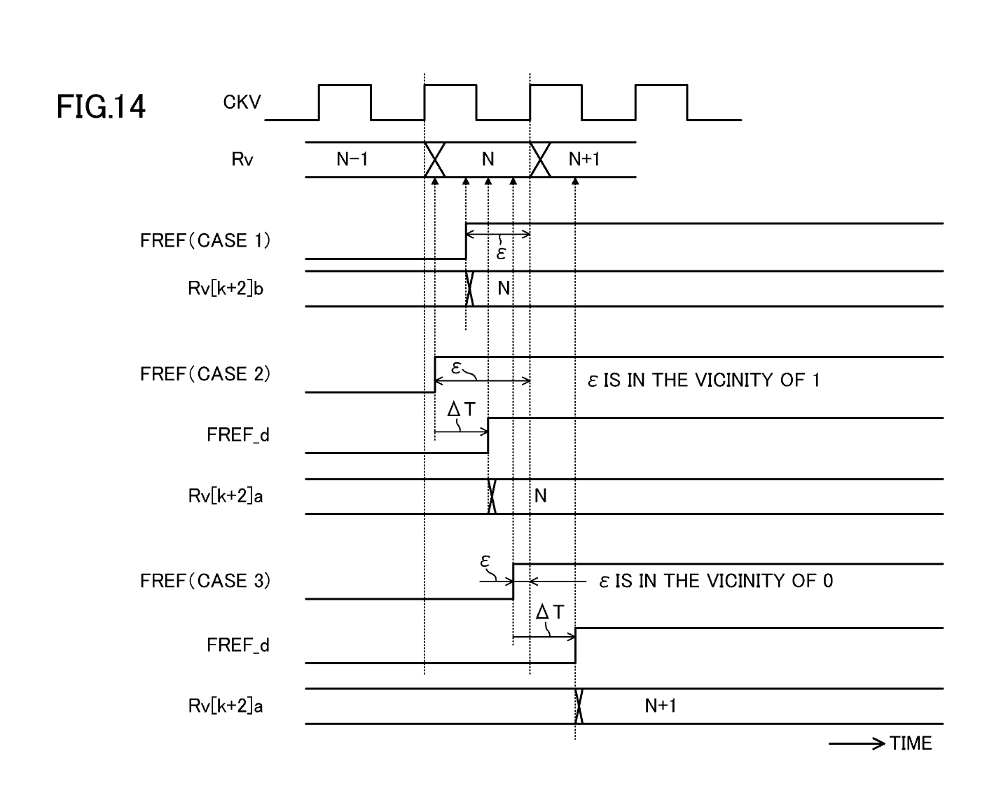

As described above, FIG. 14 is a diagram for describing that, as described above, in the oscillating signal phase information selector 180, by selecting one of Rv1, Rv2, and Rv3 based on the phase difference ε, the correct oscillating signal phase information Rv[k+1] can be invariably output.

As shown for the reference signal FREF (case 1) of FIG. 14, when a space between the rising edges of the clock signal CKV and the reference signal FREF is large enough to satisfy the specified setup time or hold time of the latch circuit, there is not a risk that the metastable state occurs in the latch circuit 803, and the correct oscillating signal phase information Rv[k+1] can be output by the selector 80 selecting Rv1 from the inputs Rv1, Rv2, and Rv3.

Also, as shown for the reference signal FREF (case 2) and the reference signal FREF (case 3) of FIG. 14, when the space between the rising edges of the clock signal CKV and the reference signal FREF is close enough to fail to satisfy the specified setup time or hold time of the latch circuit, there is not a risk that the metastable state occurs in the latch circuit 801 which latches using the clock signal FREF_d which is obtained by delaying the reference signal FREF by a predetermined period of time ΔT (here, half the cycle of the clock signal CKV). Note that, as shown for the reference signal FREF (case 3) of FIG. 14, when the phase difference ε is smaller than a normalized value which is obtained by dividing ΔT by the time period of one cycle of the clock signal CKV, a value which is greater than Rv[i] by one may be latched instead of the Rv[i] which should be originally latched, due to the delay of the value data. Therefore, in the case of the reference signal FREF (case 3) of FIG. 14, if the selector 80 selects a value (i.e., Rv3) obtained by subtracting one from Rv2 of the inputs Rv1, Rv2, and Rv3, the selector 80 can output the correct oscillating signal phase information Rv[k+1]. As shown in the reference signal FREF (case 2) of FIG. 14, when the phase difference is greater than a normalized value which is obtained by dividing ΔT by the time period of one cycle of the clock signal CKV, the value Rv[i] which should be originally latched is latched even if the delayed data is latched. In the case of the reference signal FREF (case 2) of FIG. 14, if the selector 80 selects Rv2 from the inputs Rv1, Rv2, and Rv3, the selector 80 can output the correct oscillating signal phase information Rv[k+1].

Thus, even if the oscillating signal phase information selector 180 of FIG. 13 is used instead of the oscillating signal phase information selector 70 of FIG. 10, an error in the oscillating signal phase information Rv[k] caused by the metastable state can be similarly reduced or avoided. In addition, the number of high-speed latch circuits for reclocking can be reduced compared to the conventional art, whereby power consumption can be reduced compared to the conventional art.

Note that, in the digital PLL frequency synthesizers 101 and 102 of the first and second embodiments, it has been assumed that the digital phase detector 118 has the configuration of FIGS. 18 and 19 described in the background section. The present disclosure is not limited to this. For example, the digital phase detector 118 may be replaced with one which is described in Japanese Patent Publication No. 2010-21686 (hereinafter referred to as PATENT DOCUMENT 3) or Japanese Patent Publication No. 2010-119077 (hereinafter referred to as PATENT DOCUMENT 4).

Also, in the digital PLL frequency synthesizers 101 and 102 of the first and second embodiments, it has been assumed that the oscillator 115 is a digitally controlled oscillator (DCO) which is controlled based on a digital value output from the gain adjuster 114. The present disclosure is not limited to this. The oscillator 115 may include a DA converter which converts a digital value output from the gain adjuster 114 into an analog value, and a voltage controlled oscillator (VCO) which is controlled based on a voltage corresponding to the analog signal obtained by the conversion.

The present disclosure is not limited to those precise embodiments, and various changes and modifications may be effected therein without departing from the scope or spirit of the disclosure. For example, the oscillating signal phase information estimation section 20 or the selector 12, etc., of the present disclosure may be added to the digital PLL frequency synthesizer of PATENT DOCUMENT 3 (FIG. 4) or PATENT DOCUMENT 4 (FIG. 11), whereby the risk of the metastable state caused by the asynchronicity of a clock generated from the output signal of an oscillator and a reference signal can, of course, be reduced or avoided.

### Example Applications

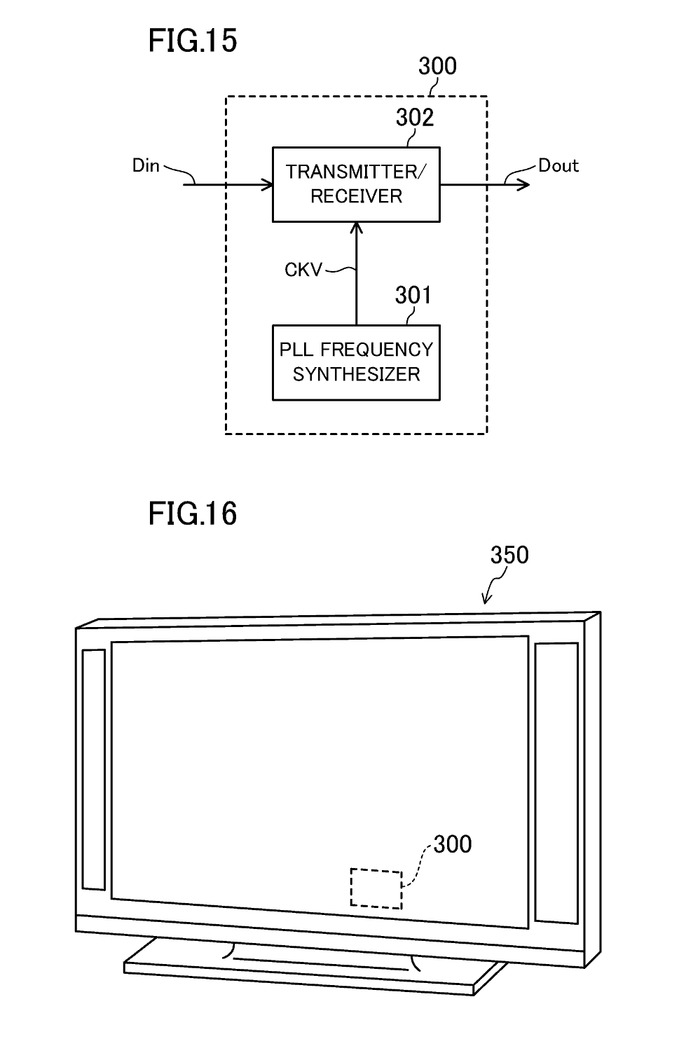

FIG. 15 is a diagram showing a configuration of a wireless communication device 300 as an example application. The wireless communication device 300 of FIG. 15 includes a digital PLL frequency synthesizer 301, and a transmitter/receiver 302 which receives and processes a data signal Din in synchronization with a clock signal CKV, and transmits and outputs the processed data as a data signal Dout. Note that the digital PLL frequency synthesizer 301 is either of the digital PLL frequency synthesizers 101 and 102 of the first and second embodiments. The wireless communication device 300 may be used as, for example, a tuner included in a television set 350 of FIG. 16.

As described above, the PLL frequency synthesizer of the present disclosure can avoid or reduce a deterioration in phase-noise characteristics and reduce power consumption.

What is claimed is:

1. A PLL frequency synthesizer comprising:
an oscillator configured to oscillate at an oscillation frequency corresponding to a digital control code;
a counter configured to count the number of waves of an oscillating signal generated based on an output signal of the oscillator, and output the count value;
a first latch circuit configured to latch the count value based on a reference signal, and output the resulting value as first oscillating signal phase information;
an oscillating signal phase information estimation section configured to estimate an output value of the first latch circuit, and output the resulting value as second oscillating signal phase information;
a digital phase detector configured to output, as a digital value, a phase difference value between the reference signal and the oscillating signal;
a second latch circuit configured to latch the phase difference value based on the reference signal, and output the resulting value as phase difference information;
a selector configured to switch an output signal from the first oscillating signal phase information to the second oscillating signal phase information, based on a lock detection signal;
a third latch circuit configured to latch the output of the selector based on the reference signal, and output the resulting value as third oscillating signal phase information;
a cumulative adder configured to cumulatively add a frequency control word for setting the oscillation frequency of the oscillator, every predetermined number of cycles of the reference signal, and output the resulting value as reference phase information;
a phase comparator configured to calculate a phase error from the reference phase information, the phase difference information, and the third oscillating signal phase information, and output a phase error signal; and
an oscillation frequency controller configured to receive the output signal of the phase comparator, and output the digital control code.

2. The PLL frequency synthesizer of claim 1, further comprising:
a digital loop filter coupled between the phase comparator and the oscillation frequency controller.

3. The PLL frequency synthesizer of claim 1, wherein
the oscillating signal phase information estimation section generates the second oscillating signal phase information from a phase difference change amount which is a difference between a current output value of the second latch circuit and a previous output value preceding by a predetermined number of cycles of the reference signal, the value of the integer part of the frequency control word, the value of the fractional part of the frequency control word, and the output of the third latch circuit.

4. The PLL frequency synthesizer of claim 1, wherein
the counter has a function of stopping counter operation.

5. The PLL frequency synthesizer of claim 4, wherein
the counter invariably or intermittently stops the counter operation when the selector is in a mode in which the selector selects the second oscillating signal phase information.

6. The PLL frequency synthesizer of claim 1, wherein
when a fluctuation in the first oscillating signal phase information has converged within a predetermined range, the PLL frequency synthesizer is determined to be in a stable state.

7. The PLL frequency synthesizer of claim 1, further comprising:
a latch determination circuit configured to determine whether or not the estimation of the oscillating signal phase information estimation section is correct, based on the output value of the first latch circuit.

8. The PLL frequency synthesizer of claim 7, wherein
the lock detection signal is switched based on the determination result of the latch determination circuit.

9. A PLL frequency synthesizer comprising:
an oscillator configured to oscillate at an oscillation frequency corresponding to a digital control code;
a counter configured to count the number of waves of an oscillating signal generated based on an output signal of the oscillator, and output the count value;
a first latch circuit configured to latch the count value based on a reference signal using a first clock signal, and output the resulting value as first oscillating signal phase information;
a digital phase detector configured to output, as a digital value, a phase difference value between the reference signal and the oscillating signal;
a second latch circuit configured to latch the phase difference value based on the reference signal, and output the resulting value as phase difference information;
a third latch circuit configured to latch the count value based on a second clock signal, latch the latched value based on the reference signal using the first clock signal, and output the resulting value as second oscillating signal phase information;
a selector configured to select one of the first oscillating signal phase information, the second oscillating signal phase information, and a value obtained by adding a predetermined value to the second oscillating signal phase information, and output the selected value as third oscillating signal phase information;
a cumulative adder configured to cumulatively add a frequency control word for setting the oscillation frequency of the oscillator, every predetermined number of cycles of the reference signal, and output the resulting value as reference phase information;
a phase comparator configured to calculate a phase error from the reference phase information, the phase difference information, and the third oscillating signal phase information, and output a phase error signal; and
an oscillation frequency controller configured to receive the output signal of the phase comparator, and output the digital control code.

10. The PLL frequency synthesizer of claim 9, further comprising:
a digital loop filter coupled between the phase comparator and the oscillation frequency controller.

11. The PLL frequency synthesizer of claim 9, wherein
the first clock signal is the reference signal or a signal which is synchronous with the reference signal and which has the same cycle as that of the reference signal,
the second clock signal is synchronous with the oscillating signal and has a predetermined phase difference from the oscillating signal,
the second oscillating signal phase information is selected and output if the phase difference information is smaller than a first predetermined value or smaller than or equal to the first predetermined value, a value obtained by adding one to the second oscillating signal phase information is selected and output if the phase difference information is greater than or equal to a second predetermined value or exceeds the second predetermined value, and the first oscillating signal phase information is selected and output if the phase difference information is greater than or equal to the first predetermined value or exceeds the first predetermined value, and is smaller than the second predetermined value or smaller than or equal to the second predetermined value.

12. The PLL frequency synthesizer of claim 11, wherein
the first clock signal is the reference signal,
the second clock signal is an inverted version of the oscillating signal,
the first predetermined value is 0.25 when a time difference between a rising edge of the reference signal and a rising edge of the oscillating signal is normalized by the time period of one cycle of the oscillating signal, and the second predetermined value is 0.75 when the time difference between the rising edge of the reference signal and the rising edge of the oscillating signal is normalized by the time period of one cycle of the oscillating signal.

13. The PLL frequency synthesizer of claim 9, wherein
the first clock signal is the reference signal or a signal which is synchronous with the reference signal and which has the same cycle as that of the reference signal,
the second clock signal is a signal which is obtained by delaying the first clock signal by a predetermined period of time,
a value obtained by subtracting one from the second oscillating signal phase information is selected and output if the phase difference information is smaller than a first predetermined value or smaller than or equal to the first predetermined value, the second oscillating signal phase information is selected and output if the phase difference information is greater than or equal to a second predetermined value or exceeds the second predetermined value, and the first oscillating signal phase information is selected and output if the phase difference information is greater than or equal to the first predetermined value or exceeds the first predetermined value, and is smaller than the second predetermined value or smaller than or equal to the second predetermined value.

14. The PLL frequency synthesizer of claim 13, wherein
the first clock signal is the reference signal,
the second clock signal is a signal which is obtained by delaying the reference signal by about half the cycle of the oscillating signal,
the first predetermined value is 0.25 when a time difference between a rising edge of the reference signal and a rising edge of the oscillating signal is normalized by the time period of one cycle of the oscillating signal, and the second predetermined value is 0.75 when the time difference between the rising edge of the reference signal and the rising edge of the oscillating signal is normalized by the time period of one cycle of the oscillating signal.

15. A wireless communication device comprising:
at least one of a receiver circuit and a transmitter circuit each of which includes the PLL frequency synthesizer of claim 1.

16. A wireless communication device comprising:
at least one of a receiver circuit and a transmitter circuit each of which includes the PLL frequency synthesizer of claim 9.
